(19) United States
(12) Patent Application Publication
(10) Pub. No.: US 2025/0245396 A1
(43) Pub. Date: Jul. 31, 2025

(54) SYSTEMS AND METHODS FOR DETERMINING BIT BEHAVIOR

(71) Applicant: Schlumberger Technology Corporation, Sugar Land, TX (US)

(72) Inventors: Feng Feng, Beijing (CN); Yupeng Xu, Beijing (CN); Bo Liu, Beijing (CN); Gang Xu, Beijing (CN); Rahul R. Bijai, Spring, TX (US); James Masdea, Houston, TX (US); Balasubramanian Durairajan, Sugar Land, TX (US); Yuelin Shen, Spring, TX (US); Alexei Jozef Barr, Pearland, TX (US)

(21) Appl. No.: 18/426,453

(22) Filed: Jan. 30, 2024

(51) Int. Cl. G06F 30/20; E21B 49/00

(52) U.S. Cl. CPC G06F 30/20; E21B 49/00; E21B 2200/20

(57) ABSTRACT

A method of predicting behavior of a downhole tool implemented in a wellbore includes receiving geometry data associated with the downhole tool. The geometry data may indicate a bend angle of the downhole tool based on the tool being bent at a bend point. The method further includes, based on the geometry data, generating a simplified model of the downhole tool including determining an effective bend point and an effective bend angle based on the longitudinal axis of the wellbore. The method further includes receiving operational parameters for the downhole tool and simulating an operation of the downhole tool based on applying the operational parameters to the simplified model. The method further includes determining one or more behavior characteristics of the downhole tool based on the simulation.

### BACKGROUND OF THE DISCLOSURE

Wellbores may be drilled into a surface location or seabed for a variety of exploratory or extraction purposes. For example, a wellbore may be drilled to access fluids, such as liquid and gaseous hydrocarbons, stored in subterranean formations and to extract the fluids from the formations. Wellbores used to produce or extract fluids may be formed in earthen formations using earth-boring tools such as drill bits for drilling wellbores and reamers for enlarging the diameters of wellbores.

In many cases, it may be desirable to understand and/or characterize the behavior of downhole tools in response to a specific downhole operation and/or in response to specific downhole conditions. Downhole systems, however, may typically be very complex and intricate, with many components interacting. Accordingly, performing a detailed analysis of the downhole system by modeling and/or simulating the behavior of many or all of these components may present a significant computational burden and may be overly complicated. In some cases, it may be desirable to isolate the response of a specific downhole tool, such as a drill bit, in order to focus in on the specific behavior of that component and/or simulate the operation with respect to that component in a simplified and expedited manner. Accordingly, systems and methods for simplifying the modeling and/or simulation of a downhole operation in order to capture the behavior of a specific downhole component may be advantageous.

### SUMMARY

In some embodiments, a method of predicting behavior of a downhole tool implemented in a wellbore includes receiving geometry data associated with the downhole tool. The geometry data may indicate a bend angle of the downhole tool based on the tool being bent at a bend point. The method further includes, based on the geometry data, generating a simplified model of the downhole tool including determining an effective bend point and an effective bend angle based on the longitudinal axis of the wellbore. The method further includes receiving operational parameters for the downhole tool and simulating an operation of the downhole tool based on applying the operational parameters to the simplified model. The method further includes determining one or more behavior characteristics of the downhole tool based on the simulation. In some embodiments, the method is performed by a system. In some embodiments, the method is performed as instructions stored on computer-readable media.

This summary is provided to introduce a selection of concepts that are further described in the detailed description. This summary is not intended to identify key or essential features of the claimed subject matter, nor is it intended to be used as an aid in limiting the scope of the claimed subject matter. Additional features and aspects of embodiments of the disclosure will be set forth herein, and in part will be obvious from the description, or may be learned by the practice of such embodiments.

### BRIEF DESCRIPTION OF THE DRAWINGS

In order to describe the manner in which the above-recited and other features of the disclosure may be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is an example of a downhole system, according to at least one embodiment of the present disclosure;

FIG. 2 illustrates an example environment in which a bit behavior system is implemented, according to at least one embodiment of the present disclosure;

FIG. 3 illustrates an example implementation of a bit behavior system as described herein, according to at least one embodiment of the present disclosure;

FIG. 4-1 illustrates a schematic representation of an example implementation of a steering system that may be utilized to steer a downhole tool, according to at least one embodiment of the present disclosure;

FIG. 4-2 illustrates an example of a simplified downhole model of the steering system of FIG. 4-1 as described herein, according to at least one embodiment of the present disclosure;

FIG. 4-3 illustrates a schematic representation of an example implementation of a steering system that may be utilized to steer a downhole tool, according to at least one embodiment of the present disclosure;

FIG. 4-4 illustrates an example of a simplified downhole model of the steering system of FIG. 4-3 as described herein, according to at least one embodiment of the present disclosure;

FIG. 5 illustrates an example workflow of the bit behavior system as described herein, according to at least one embodiment of the present disclosure;

FIG. 6 is an example of various features of a report generated by the bit behavior system as described herein, according to at least one embodiment of the present disclosure;

FIG. 7 illustrates a flow diagram for a method or a series of acts for predicting behavior of a downhole tool implemented in a wellbore as described herein, according to at least one embodiment of the present disclosure; and

FIG. 8 illustrates certain components that may be included within a computing system.

### DETAILED DESCRIPTION

This disclosure generally relates to systems and methods for determining the behavior of a downhole tool in association with a simulated operation of the downhole tool in a wellbore. A computer-implemented bit behavior system may receive a variety of types of data associated with one or more downhole tools, wellbores, formations, and/or operations of interest. Based on the data, the bit behavior system may determine a geometry of the downhole system. The geometry of the system may include one or more of angles, lengths, positions, orientations, or other geometry associated with the geometry of a specific downhole tool. In many cases, downhole systems may be intricate, detailed, and/or complex, and it may not be necessary to analyze and/or characterize one or more of the behavior, response, movements, or other features of each component of the downhole system. For example, in cases where the response of a drill bit is of interest, it may be desirable to model the behavior of the drill bit without determining the responses of one or more additional components. In some embodiments, the bit behavior system determines a simplified downhole model in order to focus in on the response of a specific downhole tool, such as a drill bit. The bit behavior system may determine a simplified geometry for the downhole tool which may align one or more lengths, angles, positions, etc., with a longitudinal axis of the wellbore. The bit behavior system may apply operational parameters for a simulated operation of the downhole tool, such as weight on bit, surface RPM, motor RPM, other operational parameters, or combinations thereof. These operational parameters may be applied to the simplified model and in this way the bit behavior system may isolate the behavior of the bit without considering the response of one or more additional downhole components.

The bit behavior system may simulate specific downhole conditions, formation properties, operational parameters, bit properties, other downhole parameters, or combinations thereof for a specific downhole operation to determine various behavior characteristics for the bit in response to the simulated operation. For example, the bit behavior system may determine one or more behavior characteristics related to one or more of durability, steerability, stability, or efficiency of the bit. In this way, the bit behavior system may facilitate understanding how a certain downhole tool may respond to being implemented in a given downhole operation and/or may provide valuable behavior characteristics for the bit without having to consider the complexities of the larger downhole system generally.

As will be discussed in further detail below, the present disclosure includes a number of practical applications having features described herein that provide benefits and/or solve problems associated with simulating the behavior of a downhole tool. Some example benefits are discussed herein in connection with various features and functionalities provided by a bit behavior system implemented on one or more computing devices. It will be appreciated that benefits explicitly discussed in connection with one or more embodiments described herein are provided by way of example and are not intended to be an exhaustive list of all possible benefits of the bit behavior system.

For example, as described herein, downhole systems may typically be complex, intricate systems and may include numerous components performing various functions of a downhole operation. As an illustrative example, simulating a complete and/or accurate representation of a downhole system may include modeling components of the downhole system including the various components of the drill string, drive/steering systems, numerous downhole tools, the drill rig, and other components. The components may interact with each other and/or with the wellbore in unique ways. Such a simulation may take into account loading on each component, including dynamic or changing loading on each component as well as inertial movement of components. Drive systems such as a rotary steering system or a bent downhole motor may actively influence one or more of the direction, rotation, orientation, other spatial or other parameters, or combinations thereof of various components. In this way, simulation of a downhole system may be difficult to achieve at a high level of completeness, and where possible may result in slow and costly computations. Additionally, it may be difficult to characterize and/or understand the behavior of a specific downhole tool, and in response to specific applied parameters, among the many factors at play in a complex simulation.

The bit behavior system of the present disclosure may simplify the modeling of the downhole system in order to isolate the behavior of a specific downhole tool. For example, by simplifying the geometry of a downhole steering system to represent the downhole tool with an effective bend angle at an effective bend point relative to (e.g., on) the longitudinal axis of the wellbore, operational parameters of interests may be applied to the downhole tool at (or near) the effective bend point to understand how the bit specifically responds to those parameters. This may facilitate isolating the specific bit behavior under the given conditions of the simulation and in response to specific (e.g., steering) parameters applied to the bit, which may be difficult to achieve in a more complex model where the bit behavior may be mixed and/or influenced by the behavior of various other components. In this way, the simplified model may facilitate understanding how the bit alone will respond and/or behave due to steering/drive effects, without being influenced by the effects that other downhole components may have on the bit. This simplified modeling performed by the bit behavior system may additionally result in simpler computations, which may provide the additional benefit of performing the simulation faster, more efficiently, and at lower cost.

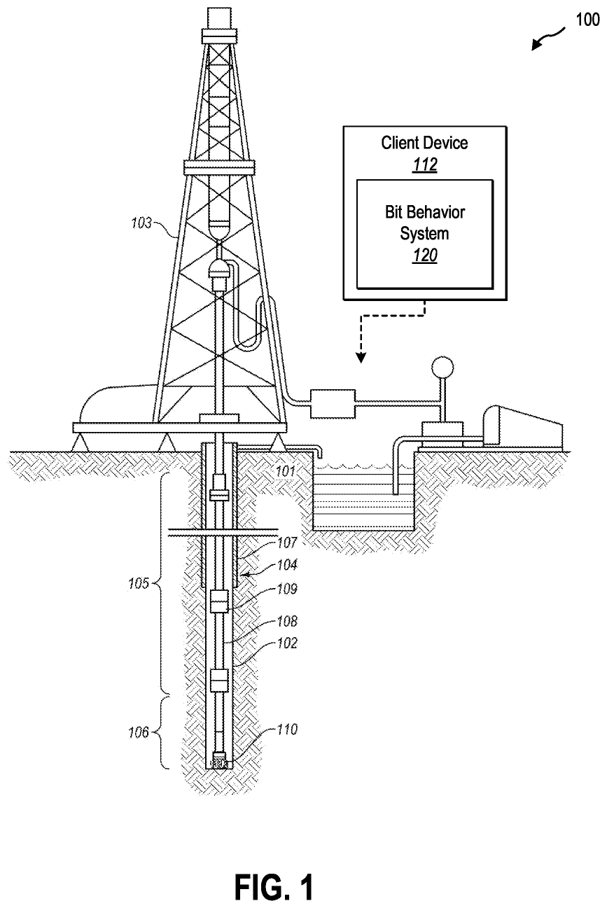

Additional details will now be provided regarding systems described herein in relation to illustrative figures portraying example implementations. For example, FIG. 1 shows one example of a downhole system 100 for drilling an earth formation 101 to form a wellbore 102. The downhole system 100 includes a drill rig 103 used to turn a drilling tool assembly 104 which extends downward into the wellbore 102. The drilling tool assembly 104 may include a drill string 105, a bottomhole assembly (“BHA”) 106, and a bit 110, attached to the downhole end of the drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 further includes additional downhole drilling tools and/or components such as subs, pup joints, etc. The drill pipe 108 provides a hydraulic passage through which drilling fluid is pumped from the surface. The drilling fluid discharges through selected-size nozzles, jets, or other openings in the bit 110 for the purposes of cooling the bit 110 and cutting structures thereon, and for lifting cuttings out of the wellbore 102 as it is being drilled.

The BHA 106 may include the bit 110, other downhole drilling tools, or other components. An example BHA 106 may include additional or other downhole drilling tools or components (e.g., coupled between the drill string 105 and the bit 110). Examples of additional BHA components include drill collars, stabilizers, measurement-while-drilling (“MWD”) tools, logging-while-drilling (“LWD”) tools, downhole motors, underreamers, section mills, hydraulic disconnects, jars, vibration or dampening tools, other components, or combinations of the foregoing.

In general, the downhole system 100 may include other downhole drilling tools, components, and accessories such as special valves (e.g., kelly cocks, blowout preventers, and safety valves). Additional components included in the downhole system 100 may be considered a part of the drilling tool assembly 104, the drill string 105, or a part of the BHA 106, depending on their locations in the downhole system 100.

The bit 110 in the BHA 106 may be any type of bit suitable for degrading downhole materials. For instance, the bit 110 may be a drill bit suitable for drilling the earth formation 101. Example types of drill bits used for drilling earth formations are fixed-cutter or drag bits. In other embodiments, the bit 110 may be a mill used for removing metal, composite, elastomer, other materials downhole, or combinations thereof. For instance, the bit 110 may be used with a whipstock to mill into casing 107 lining the wellbore 102. The bit 110 may also be a junk mill used to mill away tools, plugs, cement, other materials within the wellbore 102, or combinations thereof. Swarf or other cuttings formed by use of a mill may be lifted to the surface 111 or may be allowed to fall downhole. The bit 110 may include one or more cutting elements for degrading the earth formation 101.

The BHA 106 may further include components for directing or steering a trajectory of the bit 110. For example, the BHA 106 may include a rotary steerable system (RSS) and/or a directional downhole motor. Based on the mechanisms of these steering systems, the BHA 106 may be directed underground to, around, and/or with respect to one or more downhole targets. In many cases, it may be advantageous to simulate, quantify, and conceptualize the behavior of the bit 110 (e.g., in isolation) in response to steering by the steering system(s). In some embodiments, the downhole system 100 includes or is associated with one or more client devices 112 with a bit behavior system 120 implemented thereon (e.g., implemented on one, several, or across multiple client devices 112). The bit behavior system 120 may facilitate simulating and determining behavior characteristics of one or more downhole tools, such as the bit 110.

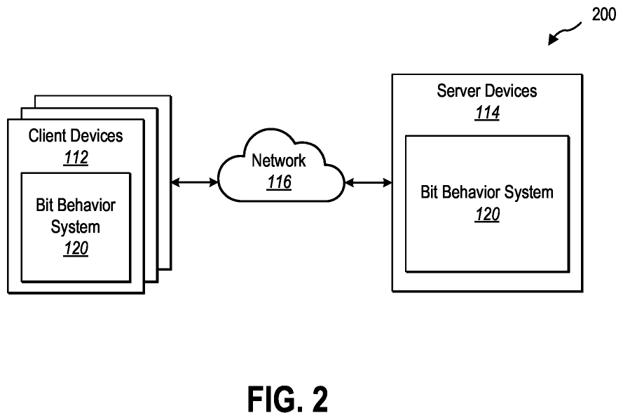

FIG. 2 illustrates an example environment 200 in which a bit behavior system 120 is implemented in accordance with one or more embodiments describe herein. As shown in FIG. 2, the environment 200 includes one or more server device(s) 114. The server device(s) 114 may include one or more computing devices (e.g., including processing units, data storage, etc.) organized in an architecture with various network interfaces for connecting to and providing data management and distribution across one or more client systems. As shown in FIG. 2, the server devices 114 may be connected to and may communicate with (either directly or indirectly) one or more client devices 112 through a network 116. The network 116 may include one or multiple networks and may use one or more communication platforms and/or technologies suitable for transmitting data. The network 116 may refer to any data link that enables transport of electronic data between devices of the environment 200. The network 116 may refer to a hardwired network, a wireless network, or a combination of a hardwired network and a wireless network. In one or more embodiments, the network 116 includes the internet. The network 116 may be configured to facilitate communication between the various computing devices via well-site information transfer standard markup language (WITSML) or similar protocol, or any other protocol or form of communication.

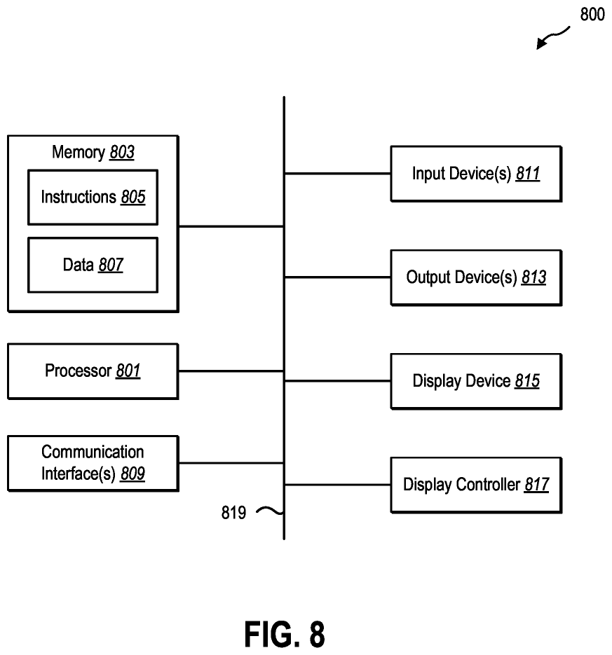

The client device 112 may refer to various types of computing devices. For example, one or more client devices 112 may include a mobile device such as a mobile telephone, a smartphone, a personal digital assistant (PDA), a tablet, a laptop, or any other portable device. Additionally, or alternatively, the client devices 112 may include one or more non-mobile devices such as a desktop computer, server device, surface or downhole processor or computer (e.g., associated with a sensor, system, or function of the downhole system), or other non-portable device. In one or more implementations, the client devices 112 include graphical user interfaces (GUI) thereon (e.g., a screen of a mobile device). In addition, or as an alternative, one or more of the client devices 112 may be communicatively coupled (e.g., wired or wirelessly) to a display device having a graphical user interface thereon for providing a display of system content. The server device(s) 114 may similarly refer to various types of computing devices. Each of the devices of the environment 200 may include features and/or functionalities described below in connection with FIG. 8.

As shown in FIG. 2, the environment 200 may include a bit behavior system 120 implemented on one or more computing devices. The bit behavior system 120 may be implemented on one or more client device 112, server devices 114, and combinations thereof. Additionally, or alternatively, the bit behavior system 120 may be implemented across the client devices 112 and/or the server devices 114 such that different portions or components of the bit behavior system 120 are implemented on different computing devices in the environment 200. In this way, the environment 200 may be a cloud computing environment, and the bit behavior system 120 may be implemented across one or more devices of the cloud computing environment in order to leverage the processing capabilities, memory capabilities, connectivity, speed, etc., that such cloud computing environments offer in order to facilitate the features and functionalities described herein.

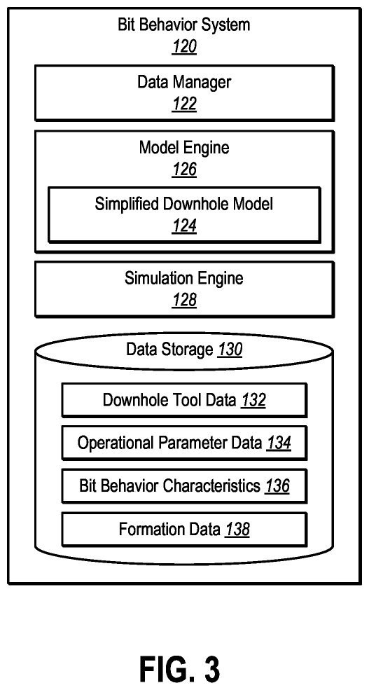

FIG. 3 illustrates an example implementation of the bit behavior system 120 as described herein, according to at least one embodiment of the present disclosure. The bit behavior system 120 may include a data manager 122, a model engine 126 for generating a simplified downhole model 124, and a simulation engine 128. The bit behavior system 120 may also include a data storage 130 having downhole tool data 132, operational parameter data 134, bit behavior characteristics 136, and formation data 138 stored thereon. While one or more embodiments described herein describe features and functionalities performed by specific components 122-128 of the bit behavior system 120, it will be appreciated that specific features described in connection with one component of the bit behavior system 120 may, in some examples, be performed by one or more of the other components of the bit behavior system 120.

By way of example, one or more of the data receiving, gathering, or storing features of the data manager 122 may be delegated to other components of the bit behavior system 120. As another example, while a simplified downhole model 124 may be generated by a model engine 126, in some instances, some or all of these features may be performed by the simulation engine 128 (or other component of the bit behavior system 120). Indeed, it will be appreciated that some or all of the specific components may be combined into other components and specific functions may be performed by one or across multiple components 122-128 of the bit behavior system 120.

Additionally, while FIG. 1, for example, depicts the bit behavior system 120 implemented on a client device 112 of the downhole system, it should be understood that some or all of the features and functionalities of the bit behavior system 120 may be implemented on or across multiple client devices 112 and/or server devices 114. For example, data may be input and/or received by the data manager 122 on a (e.g., local) client device, and the simplified downhole model 124 may be generated and/or simulated on one or more of a remote, server, or cloud device. Indeed, it will be appreciated that some or all of the specific components 122-128 may be implemented on or across multiple client devices 112 and/or server devices 114, including individual functions of a specific component being performed across multiple devices.

As mentioned above, the bit behavior system 120 includes a data manager 122. The data manager 122 may receive a variety of types of data associated with the downhole system and may store the data to the data storage 130. The data manager 122 may receive the data from a variety of sources, such as from sensors, surveying tools, downhole tools, other (e.g., client) devices, user input, etc.

In some embodiments, the data manager 122 receives downhole tool data 132. The downhole tool data 132 may include information associated with the drilling tool assembly of the downhole system. For example, the downhole tool data 132 may identify the components and configuration of the drilling tool assembly, such as a number of lengths of drill pipe, or the componentry and makeup of a BHA.

In some embodiments, the downhole tool data 132 includes bit data, or information associated with a downhole tool of the drilling tool assembly, such as a drill bit. The bit data may indicate the type of the drill bit and may identify a shape or geometry of the drill bit. The bit data may include information associated with one or more cutting elements of the bit, such as their location, orientation, type, shape, size, geometry, wear state, other information, or combinations thereof. The bit data may indicate a material composition or makeup of the bit and/or the cutting elements.

In some embodiments, the downhole tool data 132 includes information associated with a steering system of the drilling tool assembly. For example, the downhole tool data 132 may indicate a type of steering assembly, such as an RSS, or a directional downhole motor steering system. The downhole tool data 132 may identify the components of the steering system, such as stabilizers, subs (e.g., flex and/or bent subs), actuators, bearings, bent housings, blades, pads, or any other component, as well as their locations. The downhole tool data 132 may indicate an operation and/or function of the steering system. For example, the downhole tool data 132 may indicate a biasing direction and/or steering direction of the steering system. The downhole tool data 132 may indicate a direction and/or orientation (e.g., toolface orientation) of one or more components, such as an orientation of a bent or flex sub, of the bit, etc. The downhole tool data 132 may indicate an azimuth and/or inclination of the drill string at one or more locations and/or measurement depths.

In some embodiments, the downhole tool data 132 includes information associated with the (e.g., local) geometry of the BHA and/or steering system. For example, an RSS may operate based on bending sections of the BHA (e.g., utilizing one or more stabilizers as fulcrums) in order to effectuate a change of direction at the bit. The downhole tool data 132 may include information that may identify, or may facilitate determining, the geometry of one or more portions and/or components of the steering system and/or BHA in order to facilitate the modeling and/or simplifying features of the bit behavior system 120 described herein. In another example, a directional downhole motor steering system may operate based on a motor housing being able to actuate in order to bend and/or angle in order to direct the bit in a corresponding direction. The downhole tool data 132 may accordingly include information that may identify, or facilitate determining the associated geometry (e.g., geometry data).

In some embodiments, the downhole tool data 132 includes information associated with a wellbore (e.g., planned or existing). For example, the downhole tool data 132 may indicate a length, depth, size, shape, trajectory, other feature, or combinations thereof of the wellbore. In some embodiments, the data manager receives formation data 138. The formation data 138 may include information associated with a formation in which a downhole tool will traverse, penetrate, or otherwise be located. For example, the formation data 138 may include information about the geological characteristics of the rock that may be encountered during one or more downhole operations. For instance, the formation data 138 may indicate a material and/or composition of the formation including a hardness of the formation. The formation data 138 may indicate one or more layers and/or boundaries of the formation including an orientation and/or dip of the layers. The formation data 138 may indicate the presence of different particles and/or modules dispersed throughout (e.g., layers of) the formation, including the material and/or hardness of the particles. The formation data 138 may indicate the presence of holes and/or cavities dispersed throughout the formation. The formation data 138 may indicate a degree of homogeneity and/or uniformity of the formation (e.g., with respect to the particles and/or cavities). The formation data 138 may include data from gamma ray sensors, resistivity sensors, porosity sensors, density sensors, sonic sensors, calipers, core samples, any other formation data, or combinations thereof.

The data manager 122 may store any of the information associated with the downhole tool and/or drilling tool assembly to the data storage 130 as downhole tool data 132.

In some embodiments, the data manager 122 receives user input. The data manager 122 may receive the user input, for example, via any of the client devices 112 and/or server devices 114. Any of the data described herein may be input or augmented via the user input. For example, in some instances, some or all of the downhole tool data 132 is received by the data manager 122 as user input. The user input may be received in association with one or more functions or features of the bit behavior system 120, such as part of generating the simplified downhole model 124, or any other feature described herein.

In some embodiments, the data manager 122 receives operational parameter data 134. The operational parameter data 134 may be any information associated with an operation or function, either actual, planned, simulated, or otherwise, of the downhole system. For example, the operational parameter data 134 may be associated with a drilling operation of the downhole system. The operational parameter data 134 may be associated with a steering operation of the downhole system. The operational parameter data 134 may be associated with any other operation of the downhole system, such as the transit or tripping of one or more downhole tools.

The operational parameter data 134 may indicate one or more parameters of an associated operation. For example, the operational parameter data 134 may indicate a weight on bit (WOB) and/or a rate of penetration (ROP) of a downhole tool. The operational parameter data 134 may indicate a rotational speed (rotations per minute or RPM) of one or more components. For example, the operational parameter data 134 may indicate a surface RPM provided or exhibited by a surface component of the downhole system, such as due to a drill rig rotating the drilling string and/or drilling tool assembly. The operational parameter data 134 may indicate a downhole or motor RPM. The motor RPM may indicate a rotational speed of a downhole tool driven by a downhole motor. The motor RPM may be independent of the surface RPM. For example, in some cases, a downhole motor may drive a downhole tool to rotate in addition to the rotation of the (e.g., rest of the) drill string from the surface RPM. In some cases, the downhole system may not rotate with a surface RPM, and a downhole motor may drive a downhole tool to rotate solely based on the motor RPM. In this way, the rotation of a downhole tool may be driven by either a surface RPM, motor RPM, or a combination of both.

In this way, the data manager 122 receives a variety of data in order to facilitate the techniques described herein. The data manager 122 may receive the data from a variety of sources. For example, some of the data may be accessed by the data manager 122 in a database, record, or library. The data may be observed, measured, or recorded, for example, by sensors or measurement devices of the downhole system. In some embodiments, the data is received from another computing device or system associated with the bit behavior system 120. As mentioned above, some of the data may be received or input as user input by an operator or administrator of the bit behavior system 120.

In some embodiments, some or all of the data is generated, determined, or created to characterize planned, hypothetical, or simulated situations and/or operations of the downhole system. For example, while the data received and/or stored by the data manager 122 has been described herein with respect to an implementation of a downhole tool and/or downhole system in a wellbore, it should be understood that in some embodiments, some or all of the data is associated with a planned or simulated implementation of a downhole operation. For example, the data may be data associated with a downhole tool implemented in a wellbore, but may be for the purposes of simulating or testing one or more potential further operations of the downhole tool. In another example, the data may be associated purely with planning or simulating a potential or future wellbore. In this way, the techniques described herein may be applicable to a wide variety of situations and applications including both physical (existing) implementations and virtual, simulated, or planned implementations.

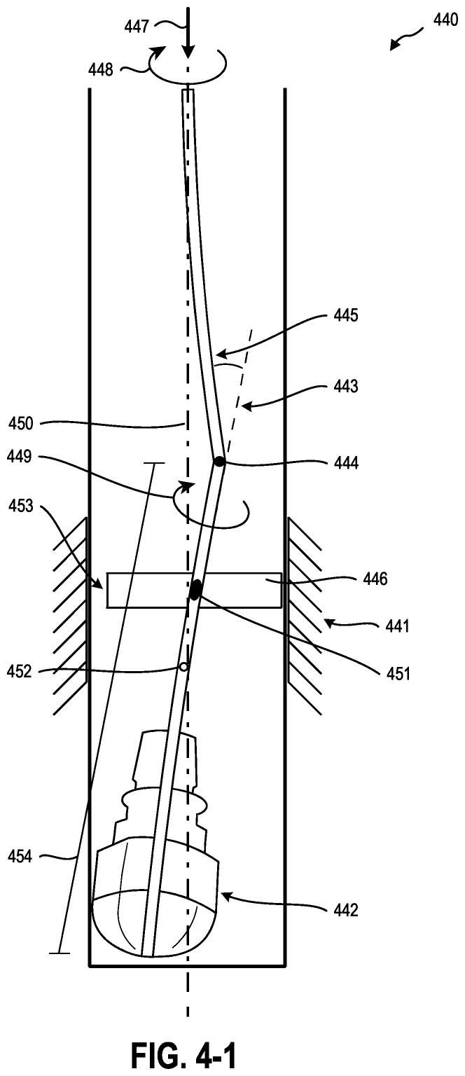

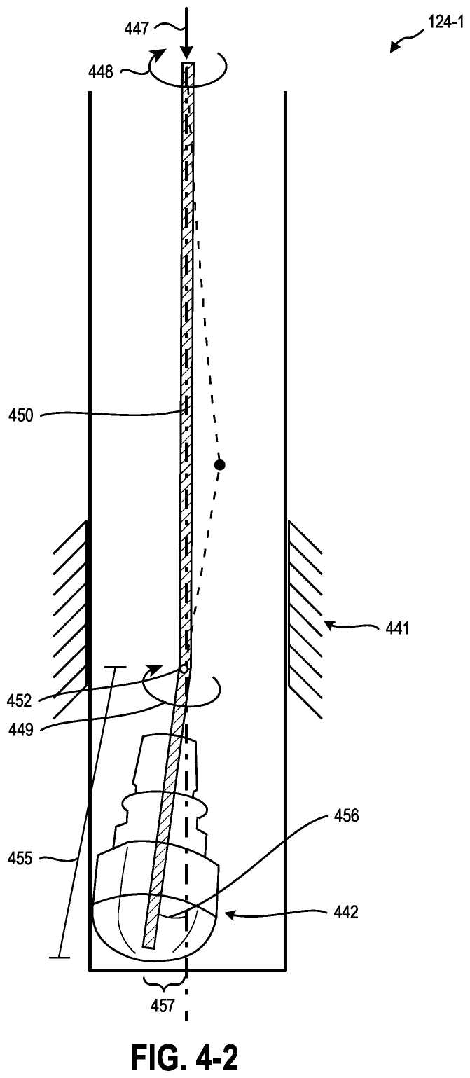

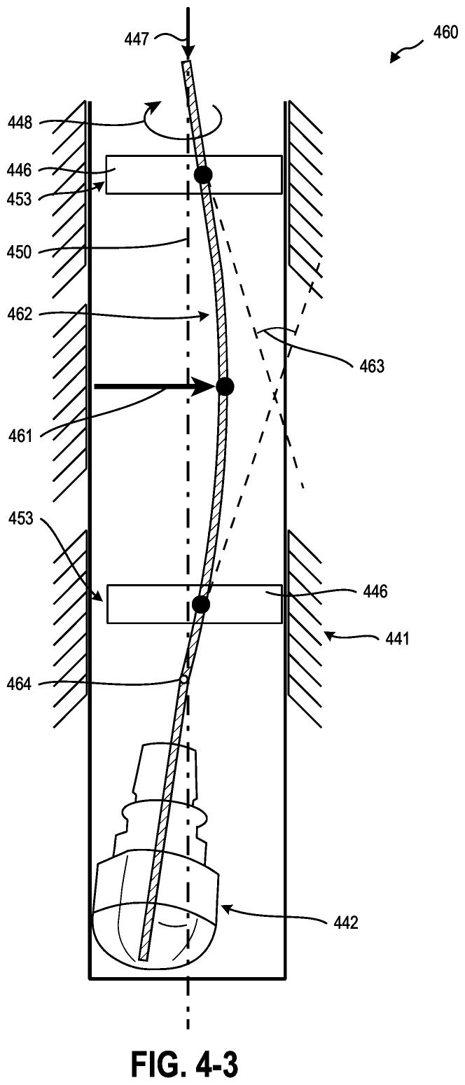

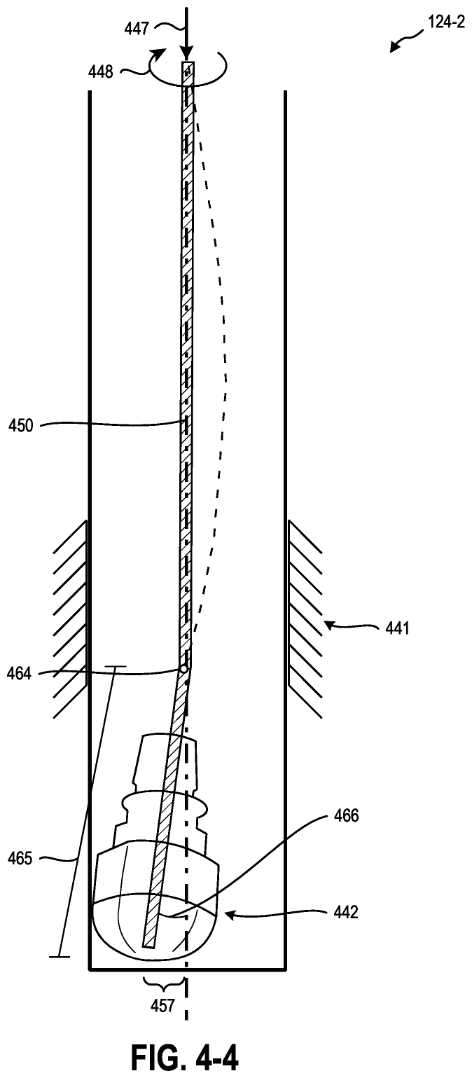

FIG. 4-1 illustrates a schematic representation of an example implementation of a steering system 440 that may be utilized to steer a downhole tool, according to at least one embodiment of the present disclosure. The steering system 440 may be a point-the-bit steering system such as may be achieved through a directional or bent downhole motor. The steering system 440 may be implemented in a wellbore 441 and may be included as part of a BHA of the downhole system. The BHA and/or the steering system 440 may be connected to one or more lengths of drill pipe in order to position the steering system 440 and/or the BHA in the wellbore 441 and/or to apply rotation, apply force, etc., to the downhole components as described herein. The steering system 440 in FIG. 4-1 may be depicted with one or more features exaggerated in order to illustrate various features and functionalities of the bit behavior system 120.

The steering system 440 may be connected to a downhole tool, such as a bit 442. As mentioned above, in some cases, it may be desirable to change a direction or orientation of the bit 442 in order to steer the bit 442. To achieve this, the steering system 440 may include one or more components that have an articulating flexure or a joint 443 that are capable of actuating to achieve a bend or angle. For example, the joint 443 may be implemented as part of a downhole motor of the steering system 440 that has an articulable bent housing design in order to change the orientation of the bit 442. The joint 443 may bend at a bend point 444 and may bend with a bend angle 445. The bend angle 445 may be an angle measured between a longitudinal axis of the bit 442 and an adjacent, bent portion of the BHA above the joint 443. In this way the bend angle 445 may be a measure of the degree or level of articulation of the joint 443.

The steering system 440 may include a stabilizer 446 to facilitate directing the bit 442. The stabilizer 446 may be a component of the steering system 440 that is configured to engage the wellbore 441. For example, the stabilizer 446 may be configured to engage the wellbore 441 and maintain a relative position of the BHA in the wellbore 441, such as in the center, or substantially in the center, of the wellbore 441. In some embodiments, this stabilizing and/or centering function of the stabilizer 446 facilitates directing the bit 442 based on the articulation of the joint 443. For example, as the joint bends, the bottom or free end of the BHA (e.g., the bit 442) may be biased or may move toward the wall of the wellbore 441 (e.g., as shown, to the left). The bit 442 may engage the wall of the wellbore 441, driving the joint 443 in an opposite direction (e.g., as shown, to the right).

In some embodiments, the stabilizer 446 engages the wellbore 441 and provides an opposite, balancing force to the bit 442 such that the bit 442 may pivot or rotate about a pivot point 451. In this way, the stabilizer 446 may act as a fulcrum for directing the bit 442 and driving it (at least somewhat) into the wall of the wellbore 441.

In some embodiments, an axial force, or WOB 447 is applied to the steering system 440 and/or BHA through the drill string. The WOB 447 may be a force resulting from the weight of the drilling tool assembly connected above or uphole of the BHA, may be an applied force from the drill rig at the surface, or a combination of both. Due to the bit 442 being angled from a centerline or longitudinal axis 450 of the wellbore 441, the axial WOB 447 may be transferred to the bit with at least some lateral component. This may result in the bit 442 engaging (and forming) the bottom of the wellbore 441 at an angle, thus steering the bit 442.

In some embodiments, the steering system 440 is rotated with a surface RPM 448. The surface RPM 448 may be a driven rotation of the entirety of the drill string from surface equipment such as the drill rig. For example, the surface RPM 448 may be transmitted to the steering system 440 and/or BHA through the lengths of drill pipe as described herein. In some embodiments, the bit 442 is rotated with a motor RPM 449. The motor RPM 449 may be a rotation of the bit 442 driven by a downhole motor (e.g., mud motor) of the steering system 440. In this way, the rotation of the bit 442 may be driven by (and/or may be described by) the surface RPM 448, the motor RPM 449, or a combination of both.

As mentioned above, the bit behavior system 120 includes a model engine 126. In some embodiments, the model engine 126 models the steering system 440 including the BHA and the bit 442. For example, the schematic representation illustrated in FIG. 4-1 may be representative of the modeling of the steering system 440 by the model engine 126.

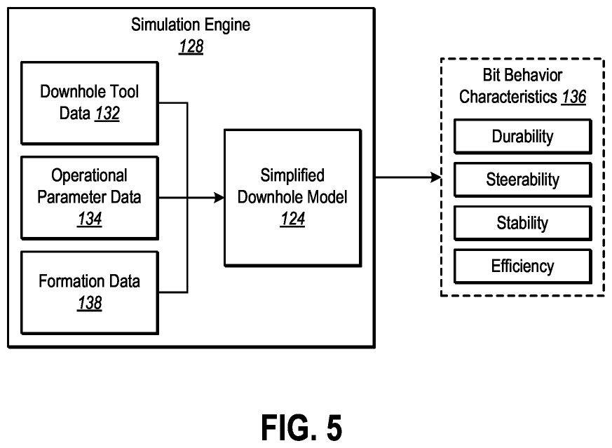

In some embodiments, the model engine 126 determines the geometry associated with the steering system 440. For example, based on the downhole tool data 132, the model engine 126 may determine the bend angle 445 of the joint 443. The model engine 126 may identify the location of the bend point 444. For example, as shown, in some cases, the bend point 444 may be offset, or not aligned with the axis 450 of the wellbore. This may be due to the bent or offset nature of the steering system 440 as described above. Similarly, the model engine 126 may identify the location of the pivot point 451 about which the bit 442 pivots. For example, as shown, in some cases, the pivot point 451 may be offset, or not aligned with the axis 450 of the wellbore. This may be due to the stabilizer 446 not being exactly the size of the gauge or diameter of the wellbore, and as the stabilizer is biased toward one side of the wellbore 441, the pivot point 451 may accordingly be slightly offset from the axis 450. As shown in FIG. 4-5, a gap 453 may be present between the stabilizer 446 and the wellbore 441 due to this effect.

In some embodiments, the model engine 126 determines a bend length 454. The bend length 454 may be a length measured from a downhole end of the bit 442 to the bend point 444. For example, the bend length 454 may be a measure from the joint 443 of the steering system 440 to the furthest downhole extent of the BHA.

The model engine 126 may determine the various loading, forces, or other dynamics applied to the bit 442. For example, the model engine 126 may identify from the downhole tool data 132 the WOB 447 applied to the BHA. The model engine 126 may identify from the downhole tool data 132 the surface RPM 448 and/or the motor RPM 449. The model engine 126 may determine the various lengths, angles, positions, etc., of the geometry of the BHA and/or the steering system 440, as well as determining the applied forces, rotations, etc., in order that the model engine 126 may model or simulate an operation of the downhole system and may predict or determine the resulting response or behavior of the bit 442. The model engine 126 may determine any other dynamic, such as rate of penetration (ROP) applied or exhibited by the downhole system in order to model the response of the bit 442.

As discussed above, the downhole system may include a number of components and/or tools positioned throughout the length of the drilling tool assembly. For example, the drilling tool assembly may include many lengths of drill pipe, collars, subs, tool joints, stabilizers, drill bits and reamers, steering systems, and other components. This intricate system of components may represent a complex and dynamic system which may be difficult to model and characterize. For example, the components may all be (at least indirectly) connected, and the movement, forces, torques, stresses, etc., exhibited by one component may accordingly affect those exhibited by other components. Additionally, many of the components may engage the wellbore wall, which may further affect the behavior of one or more components. Further, the alignment (or lack thereof) of the components of the downhole system with the wellbore axis 450 may further complicate the modeling of component behavior. For example, as discussed above, the bend point 444 and the pivot point 451 may be offset from the axis 450 of the wellbore 441. Accordingly, the BHA, steering system 440, bit 442, etc., may not be aligned with the axis 450 of the wellbore 441, making it computationally more difficult to model the behavior of the bit 442 (e.g., in relation to the wellbore 441). This effect may be even more evident when considering that similar misalignment may be propagated throughout many components of the drill string, as the drill string and the wellbore 441 may not typically be exactly straight, aligned, and vertical, but may often exhibit bent and/or curved geometries. Thus, attempting to simulate bit behavior by modeling and accounting for all of the components, details, and geometries of the downhole system may be overly complicated, and may be computationally difficult and/or slow.

In some embodiments, the model engine 126 generates a simplified downhole model 124-1. The simplified downhole model 124-1 may include a simplified representation of one or more of the bit 442, the BHA, and/or the steering system 440. For example, based on the downhole tool data 132 and/or based on the lengths, positions, angles, etc., of the geometries discussed above, the model engine 126 may determine an effective bend point 452. The effective bend point 452 may be a point located at the intersection between a longitudinal axis of the bit 442 and the wellbore axis 450. In this way, the effective bend point 452 may be located at and/or aligned with the axis 450. Due to the geometry of the steering system 440, the effective bend point 452 may be located downhole from the bend point 444.

FIG. 4-2 illustrates an example of the simplified downhole model 124-1 of the steering system 440 as described herein, according to at least one embodiment of the present disclosure. The model engine 126 may generate the simplified downhole model 124-1 to facilitate simulating and/or characterizing the behavior of the bit 442. For example, the model engine 126 may determine an effective bend length 455 for the simplified downhole model 124-1. The effective bend length 455 may be measured from the end of the bit 442 to the effective bend point 452. The effective bend length 455 may extend from the wellbore axis 450 based on the effective bend point 452 being located at the wellbore axis 450. For example, the effective bend length 455 may be angled from the wellbore axis 450 by an effective bend angle 456. Due to the mechanics of the bending action of the steering system 440 (e.g., the geometry of the steering system 440 pivoting about the pivot point 451), the effective bend length 455 may be shorter than the bend length 454, and the effective bend angle 456 may be smaller than the bend angle 445. In some embodiments, the model engine 126 determines, based on the geometries discussed above, the effective bend angle 456 in order to facilitate determining the effective bend length 455, for example, by implementing trigonometric analyses. For example, the model engine 126 may determine an offset distance 457 of the end or tip of the bit 442 from the wellbore axis 450. Based on the offset distance 457 and the effective bend angle 456, the model engine 126 may calculate the effective bend length 455 using trigonometric functions. In this way, the simplified downhole model 124-1 may simulate the geometry of the steering system 440 as if it were aligned and/or bent at the wellbore axis 450. For example, as shown in FIG. 4-2 the simplified downhole model 124-1 may represent the rest of the drill string as straight or aligned with the wellbore axis 450. Accordingly, the simplified downhole model 124-1 may simplify the downhole system from a complex, detailed system, to a much simpler system that is focused on the bit 442 and its relation to the wellbore 441.

The simplified model 124-1 may facilitate modeling the behavior and/or response of the bit 442 to one or more applied downhole stimuli. For example, one or more of the WOB 447, the surface RPM 448, and the motor RPM 449 may be simulated for the bit 442 based on the simplified geometry of the simplified downhole model 124-1 with respect to the wellbore. In some embodiments, the effective bend point 452 is modeled as a fixed point, and one or more applied downhole dynamics may be simulated for the bit 442 at the (e.g., fixed) effective bend point 452. For example, the WOB 447 may be simulated as an applied force on the bit 442 from the effective bend point 452 (e.g., taking into account the component forces due to the effective bend angle 456). In another example, the surface RPM 448 may be applied to the bit 442 from the effective bend point 452 by simulating the effective bend length (e.g., angled at the effective bend angle 456) rotating about the wellbore axis 450. In another example, the motor RPM 449 may be applied to the bit 442 from the effective bend point 452 by simulating the bit 442 (and/or the effective bend length 455) rotating about its own longitudinal axis at the motor RPM. In some embodiments, both the motor RPM 448 and the motor RPM 449 may be applied in this way to represent a compound rotation of the bit 442. In this way, the behavior of the bit 42 may be simulated in a simplified manner by focusing in on the specific angles, lengths, forces, etc., relevant to the bit 442 while not considering some of the more detailed complexities of the intricate downhole system as a whole.

FIG. 4-3 illustrates a schematic representation of an example implementation of a steering system 460 that may be utilized to steer a downhole tool, according to at least one embodiment of the present disclosure. The steering system 460 may be an RSS. As will be described in detail below, the techniques described herein may be equally applicable to downhole systems implementing an RSS, for example, in addition to or as an alternative to a directional downhole motor steering system.

The steering system 460 may be included as part of a BHA of the downhole system and may be connected to one or more lengths of drill pipe at an uphole end in order to position the steering system 460 and/or the BHA in the wellbore 441, and/or to apply rotation, force, etc., to the downhole components as has been described herein. The steering system 460 in FIG. 4-3 may be depicted with one or more features exaggerated in order to illustrate various features and functionalities of the bit behavior system 120.

The steering system 460 may be a point-the-bit steering system and may direct or steer the bit 442 by forcing the bending of one or more components. For example, the steering system 460 may apply a biasing force 461 to a flexible component 462 uphole of the bit 442. The biasing force 461 may be applied based on a stabilizer, actuator, or other downhole tool contacting the wall of the wellbore 441. The biasing force 461 may cause the flexible component 462 to bend. For example, the steering system 460 may include one or more stabilizers 446 which may contact the wall of the wellbore 441 and may counteract the biasing force 461. This may cause the flexible component 462 to bend between the stabilizers 446, with the stabilizers 446 acting like fulcrums for the bending of the flexible component 462. Based on the bit 442 being positioned downhole from the bending of the flexible component 462, the bit 442 may accordingly be pointed or directed in an opposite direction of the bend. In this way, the steering system 460 may direct the bit 442 in order to effectively steer the bit 442.

The model engine 126 may determine the geometry associated with the steering system 460. As described above in connection with the steering system 440, the geometry of the steering system 460 may exhibit one or more complexities that may make a detailed analysis of the behavior of the bit 442 computationally difficult. For example, the flexible component 462 being bent presents a complicated analysis of bit dynamics. Additionally, as may be seen in FIG. 4-3, the bend of the flexible component 462 results in the bit 442 and/or one or more other (e.g., uphole) components of the drill string being offset by a bend angle 463. As another example, the bit 442 may be offset at an angle relative to the wellbore axis 450. This may be further complicated by the fact that the fulcrum points of the stabilizers 446 for effectuating the bend of the flexible component 462 may also be offset from the wellbore axis 450 (e.g., as illustrated by the gaps 453). Accordingly, applying a WOB 447 and/or a surface RPM 448 (or any other downhole dynamic) to the steering system 460 with the complexities of the geometry as shown may be computationally demanding and inefficient for determining the resulting behavior of the bit 442.

As discussed above, the model engine 126 may generate a simplified downhole model 124-2 applicable to the steering system 460. For example, based on the downhole tool data 132, and/or based on the various lengths, positions, angles, etc., that the model engine 126 may determine for the steering system 460, the model engine 126 may determine an effective bend point 464. The effective bend point 464 may be a point located at the intersection between a longitudinal axis of the bit 442 and the wellbore axis 450. In this way, the effective bend point 464 may be located at and/or aligned with the axis 450.

FIG. 4-4 illustrates an example of the simplified downhole model 124-2 of the steering system 460 as described herein, according to at least one embodiment of the present disclosure. Similar to that described above, the model engine 126 may generate the simplified downhole model 124-2 to facilitate simulating and/or characterizing the behavior of the bit. The model engine 126 may determine an effective bend length 465 for the simplified downhole model 124-2 based on an effective bend angle 466 and an offset distance 467. The simplified downhole model 124-2 may simulate the geometry of the steering system 440 as if it consisted of straight sections and/or straight components, and as if those components were effectively bent at the wellbore axis 450 as shown. Accordingly, the simplified downhole model 124-2 may simplify the downhole system from a complex, detailed system, to a much simpler system that is focused on the bit 442 and its relation to the wellbore 441.

Just as discussed above, the simplified downhole model 124-2 may facilitate modeling the behavior and/or response of the bit 442 to one or more applied downhole dynamics. For example, the effective bend point 464 may be modeled as a fixed point, and the WOB 447 and/or surface RPM 448 may be simulated as applied to the bit 442 in relation to (e.g., from) the effective bend point 464. However, in implementations where no directional downhole motor is implemented, the bit response may be simulated via the simplified downhole model 124-2 without incorporating an applied motor RPM.

FIG. 5 illustrates an example workflow of the bit behavior system 120 as described herein, according to at least one embodiment of the present disclosure. As mentioned above, the bit behavior system 120 includes a simulation engine 128. The simulation engine 128 may run a simulation of the downhole system, and more specifically of the bit, by implementing the simplified downhole model 124 in order to determine one or more bit behavior characteristics 136 representing a simulated response or behavior of the bit.

In some embodiments, the simulation engine 128 applies the downhole tool data 132 to the simplified downhole model 124. For example, the simulation engine 128 may incorporate the downhole tool data 132 to account for various aspects of the bit such as bit type, size, shape, geometry, general wear state, etc. The simulation engine 128 may incorporate the downhole tool data 132 to account for various aspects of the cutting elements and/or contact elements of the bit, such as the location, orientation, number, type, shape, size, geometry, and individual wear state of the cutting elements and/or contact elements. The downhole tool data 132 may be incorporated in order to account for a material or composition of the bit and/or cutting elements. In this way, the simulation engine 128 may simulate various details of the bit that may be relevant to determining an accurate simulated response of the bit.

In some embodiments, the simulation engine 128 applies the operational parameter data 134 to the simplified downhole model 124. For example, as discussed above, one or more applied downhole dynamics may be simulated for the bit based on the simplified downhole model 124, such as a WOB, surface RPM, motor RPM, or any other relevant metric (e.g., ROP). As mentioned above, these applied dynamics may be applied to the bit based on the modified and/or simplified geometry of the simplified downhole model 124 in order to capture the response of the bit without modeling or simulation some of the more complex details of other components of the downhole system. For example, the WOB, surface RPM and/or motor RPM may be incorporated based on a (e.g., fixed) effective bend point and based on applying these forces, rotations, etc., from the effective bend point. In this way, the simulation engine 128 may simulate various operational parameters or conditions of interest in order to determine a corresponding response of the bit.

In some embodiments, the simulation engine 128 applies the formation data 138 to the simplified downhole model 124. For example, the simulation engine may simulate the bit interacting with (e.g., forming) the wellbore based on the wellbore having one or more properties of a particular formation of interest. The simulation engine 128 may simulate one or more geological characteristics of the rock of a formation. The simulation engine 128 may simulate one or more layers (including a formation dip) of the formation. The simulation engine 128 may simulate one or more particles, modules, and/or cavities dispersed throughout the formation. In some embodiments, the simulation engine 128 simulates a formation that is non-uniform or non-homogeneous. For example, the simulation engine 128 may simulate a formation that has one or more compositions, properties, characteristics, materials, etc., that are not uniform or consistent. For instance, the simulated formation may exhibit variations in lithology, porosity, permeability, mineral composition, physical and/or chemical characteristics, structural complexity, fluid presence and/or saturation, or any other (e.g., non-uniform) property. In this way, the simulation engine 128 may simulate the relevant details of a particular formation of interest in order to determine a corresponding response of the bit.

Based on running a simulation and implementing the simplified downhole model 124, and based on the various bit, operational, and/or formation characteristics incorporated in the simulation, the simulation engine 128 may determine one or more bit behavior characteristics 136. The bit behavior characteristics 136 may include various metrics for characterizing how the bit may move, wear, steer, respond, perform, or otherwise behave to the specific conditions of the simulation. For example, the bit behavior characteristics may characterize the forces and loading across the bit, rock removal by the bit, and shock and vibrations (e.g., accelerations) experienced by the bit. In some embodiments, the simulation engine 128 determines one or more bit behavior characteristics related to one or more of durability, steerability, stability, and efficiency of the bit.

In some embodiments the simulation engine 128 determines one or more resulting forces or contact forces based on the bit contacting the wellbore wall. For example, the simulation engine 128 may determine the forces on one or more (or each) of the cutting elements of the bit. In another example, the simulation engine 128 may determine the forces on one or more gauge pads or other contacting surfaces of the bit designed to manage the depth of cut of the bit. The simulation engine 128 may determine the forces in 3 dimensions and/or may determine the 3-dimensional components of the forces on the cutting elements and/or contacting surfaces.

In some embodiments, the determined forces facilitate determining a durability characteristic for the bit. For example, the determined forces may facilitate characterizing a level or degree of damage or wear of the cutting elements. For instance, the simulation engine 128 may determine a workrate for some or all of the cutting elements (or for the bit generally). The workrate may be associated with a force observed for the cutting element at a corresponding velocity. The simulation engine 128 may identify whether certain cutting elements or certain areas of the bit are being overloaded in order to determine how the bit may Damage or wear.

In some embodiments, the determined forces facilitate determining a steerability characteristic. For example, the determined forces may include a side cutting force associated with an ability for the bit to cut laterally, or to cut with cutting elements that are located on a lateral side of the bit. The side cutting force may be associated with an ability of the bit to turn, steer, or otherwise form the wellbore in a lateral direction. For example, the side cutting forces may be associated with the ability of the bit to produce a dogleg.

In some embodiments, the determined forces facilitate determining a stability characteristic. For example, as mentioned, the determined forces may be 3-dimensional. In some embodiments, the net force of the bit (e.g., sum of all forces acting on all of the cutting elements and/or all of the contacting surfaces) have, at least partially, a lateral or sideways component. Thus, the resulting net force may be an imbalance force which may tend to bias or push the bit in a certain direction. The simulation engine 128 may determine the imbalance force in order to characterize the stability of the bit. For example, the imbalance force may help to characterize the ability of the bit to stay straight during a straight drilling operation, and/or to stay turned during a steering operation.

In some embodiments, the simulation engine 128 determines various other metrics or measurements associated with durability. For example, the simulation engine 128 may determine one or more of torque, bending, stress, strain, shock, vibration, or any other relevant metric for the bit and/or for one or more other downhole components. These metrics may facilitate understanding how various components of the downhole system may damage or wear in response to the specific conditions of the simulation. For example, understanding the torque and bending moments exhibited by the bit may help to understand the loading on the bit or other downhole components, and may facilitate determining wear experienced by these components.

In some embodiments, the simulation engine 128 determines one or more efficiency characteristics. For example, the simulation engine 128 may determine a rate of penetrating ROP for the bit. The simulation engine 128 may determine the quality of the wellbore formed under the simulated conditions. For example, the simulation engine 128 may identify one or more areas of wellbore enlargement, such as may be due to applying a surface RPM while bending or directing the bit (e.g., with the downhole directional motor). In this way the simulation engine 128 may determine various bit behavior characteristics to facilitate understanding specific details about how the bit may respond to the specific conditions simulated for the downhole operation. This may be facilitated by the simplified downhole model 124 (e.g., the simplified geometry of the simplified downhole model 124). For example, the behavior, response, and/or effect of one or more other downhole components may be ignored or not considered in order to focus on the behavior of the bit alone. This may help to increase the computational efficiency, speed, accuracy, etc., with which the bit behavior system 120 may determine the bit behavior characteristics 136, for example, as opposed to analyzing a more complex, in-depth, representation of the downhole system.

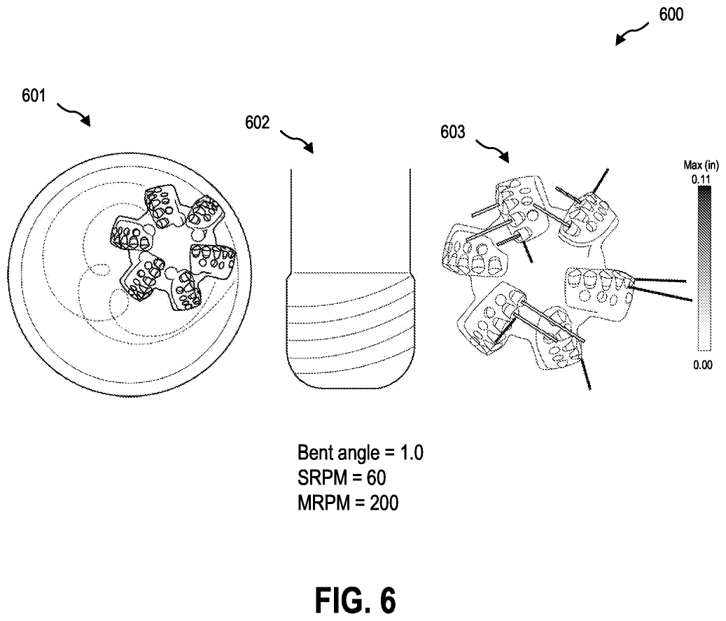

FIG. 6 is an example of a various features of a report 600 generated by the simulation engine 128, according to at least one embodiment of the present disclosure. The simulation engine 128 may generate one or more reports 600 including some or all of the features shown and described in FIG. 6.

In some embodiments, the report 600 is associated with specific operational parameters for an associated simulated downhole operation. For example, as shown, the report 600 may be associated with the operational parameters for a simulated operation having an effective bend angle of 1°, a surface RPM of 60, and a motor RPM of 200. In some embodiments, the report 600 illustrates or depicts a representation of the wellbore resulting from the simulation of the downhole operation. For example, the report 600 shows a horizontal, top-down cross-section 601, and a profile 602 of the wellbore. The cross-section 601 and the profile 602 may illustrate a hole-enlargement effect of the operation on the wellbore. The cross-section 601 may illustrate a rotational path of the bit. For example, the cross-section 601 shows that the bit follows a motion similar to whirl as it formed the wellbore due to, for example, the surface RPM being applied in conjunction with the effective bend angle of a directional downhole motor.

In some embodiments, the report 600 illustrates a representation 603 of one or more forces acting on one or more of the cutting elements of the bit. For example, the report 600 may depict a normal force and/or a tangential force on one or more of the cutting elements. This may facilitate identifying higher forces exhibited by one or more cutting elements or areas of the bit, such as to facilitate identifying an (e.g., net) imbalance force for the bit. The report 600 may depict any of the features described here, and additionally may omit any of the features described for the report 600. The report 600 may provide a representation of any of the bit behavior characteristics described herein.

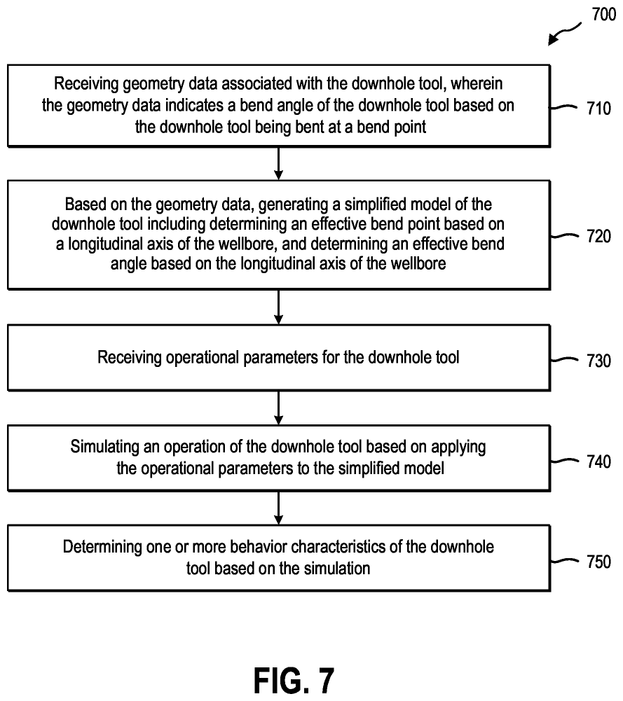

FIG. 7 illustrates a flow diagram for a method 700 or a series of acts for predicting behavior of a downhole tool implemented in a wellbore as described herein, according to at least one embodiment of the present disclosure. While FIG. 7 illustrates acts according to one embodiment, alternative embodiments may add to, omit, reorder, or modify any of the acts of FIG. 7. The acts of FIG. 7 may be performed as part of a method. Alternatively, a non-transitory computer-readable medium may include instructions that, when executed by one or more processors, cause a computing device to perform the acts of FIG. 7. In still further embodiments, a system may perform the acts of FIG. 7.

In some embodiments, the method 700 includes an act 710 of receiving geometry data associated with the downhole tool, wherein the geometry data indicates a bend angle of the downhole tool based on the downhole tool being bent at a bend point. For example, the downhole tool may include a stabilizer, and the downhole tool may be bent based on the stabilizer engaging a wall of the wellbore. The downhole tool may bend about a fulcrum point at the stabilizer. The fulcrum point may not be aligned with the longitudinal axis of the wellbore. Similarly, the bend point may not be positioned at the longitudinal axis of the wellbore. The geometry data may further indicate a bend length of the downhole tool. In some embodiments, the downhole tool is a bottom hole assembly of a downhole system, and the bottom hole assembly includes a drill bit.

In some embodiments, the method 700 includes receiving formation data. For example, the formation data may be associated with a formation that is not homogeneous. The formation data may indicate a formation dip of the formation.

In some embodiments, the method 700 includes an act 720 of, based on the geometry data, generating a simplified model of the downhole tool including determining an effective bend point based on a longitudinal axis of the wellbore, and determining an effective bend angle based on the longitudinal axis of the wellbore. The effective bend angle may be less than the bend angle. The bend point may be located downhole from the bend point. In some embodiments, the effective bend point is determined at an intersection between a longitudinal axis of the downhole tool and the longitudinal axis of the wellbore. In some embodiments, generating the simplified model includes determining an effective bend length based on the effective bend point.

In some embodiments, the method 700 includes an act 730 of receiving operational parameters for the downhole tool. For example, the operational parameters may include a weight on bit (WOB) associated with the downhole tool. The operational parameters may include a surface RPM associated with a rotational speed of the downhole tool above the bend point, and a motor RPM associated with a rotational speed of the downhole tool below the bend point. The motor RPM may be computed from a motor model using flowrate and simulated bit torque, which may change due to formation variations.

In some embodiments, the method 700 includes an act 740 of simulating an operation of the downhole tool based on applying the operational parameters to the simplified model. The operation may be a steering operation. For example, simulating the operation may include applying the WOB, surface RPM, and/or the motor RPM to the simplified model. In some embodiments, the operational parameters are applied to the downhole tool based on the effective bend angle and at the effective bend point. In some embodiments, the formation data is incorporated to simulate the downhole tool in a specific formation of interest, or to simulate the downhole tool behavior when experiencing formation variations.

In some embodiments, the method 700 includes an act 750 of determining one or more behavior characteristics of the downhole tool based on the simulation. For example, the one or more behavior characteristics may include one or more of an imbalance force exerted on the downhole tool, a side cutting force of the downhole tool, and a shock and vibration on the downhole tool. The one or more behavior characteristics may include one or more of forces exerted on cutting elements of the downhole tool, and a workrate of the cutting elements. The one or more behavior characteristics may include torque and bending associated with the downhole tool. The one or more behavior characteristics may include one or more of an enlargement of the wellbore and a quality of the wellbore.

Turning now to FIG. 8, this figure illustrates certain components that may be included within a computer system 800. One or more computer systems 800 may be used to implement the various devices, components, and systems described herein.

The computer system 800 includes a processor 801. The processor 801 may be a general-purpose single- or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 801 may be referred to as a central processing unit (CPU). Although just a single processor 801 is shown in the computer system 800 of FIG. 8, in an alternative configuration, a combination of processors (e.g., an ARM and DSP) could be used.

The computer system 800 also includes memory 803 in electronic communication with the processor 801. The memory 803 may include computer-readable storage media and may be any available media that may be accessed by a general purpose or special purpose computer system. Computer-readable media that store computer-executable instructions are non-transitory computer-readable media (device). Computer-readable media that carry computer-executable instructions are transmission media. Thus, by way of example and not limitations, embodiment of the present disclosure may comprise at least two distinctly different kinds of computer-readable media: non-transitory computer-readable media (devices) and transmission media.

Both non-transitory computer-readable media (devices) and transmission media may be used temporarily to store or carry software instructions in the form of computer readable program code that allows performance of embodiments of the present disclosure. Non-transitory computer-readable media may further be used to persistently or permanently store such software instructions. Examples of non-transitory computer-readable storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which may be used to store program code in the form of computer-executable instructions or data structures and which may be accessed by a general purpose or special purpose computer, whether such program code is stored or in software, hardware, firmware, or combinations thereof.

Instructions 805 and data 807 may be stored in the memory 803. The instructions 805 may be executable by the processor 801 to implement some or all of the functionality disclosed herein. Executing the instructions 805 may involve the use of the data 807 that is stored in the memory 803. Any of the various examples of modules and components described herein may be implemented, partially or wholly, as instructions 805 stored in memory 803 and executed by the processor 801. Any of the various examples of data described herein may be among the data 807 that is stored in memory 803 and used during execution of the instructions 805 by the processor 801.

A computer system 800 may also include one or more communication interfaces 809 for communicating with other electronic devices. The communication interface(s) 809 may be based on wired communication technology, wireless communication technology, or both. Some examples of communication interfaces 809 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

The communication interfaces 809 may connect the computer system 800 to a network. A “network” or “communications network” may generally be defined as one or more data links that enable the transport of electronic data between computer systems and/or modules, engines, or other electronic devices, or combinations thereof. When information is transferred or provided over a communication network or another communications connection (either hardwired, wireless, or a combination of hardwired or wireless) to a computing device, the computing device properly views the connection as a transmission medium. Transmission media may include a communication network and/or data links, carrier waves, wireless signals, and the like, which may be used to carry desired program or template code means or instructions in the form of computer-executable instruction or data structures and which may be accessed by a general purpose or special purpose computer.

A computer system 800 may also include one or more input devices 811 and one or more output devices 813. Some examples of input devices 811 include a keyboard, mouse, microphone, remote control device, button, joystick, trackball, touchpad, and lightpen. Some examples of output devices 813 include a speaker and a printer. One specific type of output device that is typically included in a computer system 800 is a display device 815. Display devices 815 used with embodiments disclosed herein may utilize any suitable image projection technology, such as liquid crystal display (LCD), light-emitting diode (LED), gas plasma, electroluminescence, or the like. A display controller 817 may also be provided, for converting data 807 stored in the memory 803 into one or more of text, graphics, or moving images (as appropriate) shown on the display device 815.

The various components of the computer system 800 may be coupled together by one or more buses, which may include one or more of a power bus, a control signal bus, a status signal bus, a data bus, other similar components, or combinations thereof. For the sake of clarity, the various buses are illustrated in FIG. 8 as a bus system 819.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various embodiments.

Further, upon reaching various computer system components, program code in the form of computer-executable instructions or data structures may be transferred automatically or manually from transmission media to non-transitory computer-readable storage media (or vice versa). For example, computer executable instructions or data structures received over a network or data link may be buffered in memory (e.g., RAM) within a network interface module (NIC), and then eventually transferred to computer system RAM and/or to less volatile non-transitory computer-readable storage media at a computer system. Thus, it should be understood that non-transitory computer-readable storage media may be included in computer system components that also (or even primarily) utilize transmission media.

### INDUSTRIAL APPLICABILITY

In some embodiments, a downhole system is described for drilling an earth formation to form a wellbore. The downhole system includes a drill rig used to turn a drilling tool assembly which extends downward into the wellbore. The drilling tool assembly may include a drill string, a bottomhole assembly (“BHA”), and a bit, attached to the downhole end of the drill string.

The drill string may include several joints of drill pipe connected end-to-end through tool joints. The drill string transmits drilling fluid through a central bore and transmits rotational power from the drill rig to the BHA. In some embodiments, the drill string further includes additional downhole drilling tools and/or components such as subs, pup joints, etc. The drill pipe provides a hydraulic passage through which drilling fluid is pumped from the surface. The drilling fluid discharges through selected-size nozzles, jets, or other openings in the bit for the purposes of cooling the bit and cutting structures thereon, and for lifting cuttings out of the wellbore as it is being drilled.

The BHA may include the bit, other downhole drilling tools, or other components. An example BHA may include additional or other downhole drilling tools or components (e.g., coupled between the drill string and the bit). Examples of additional BHA components include drill collars, stabilizers, measurement-while-drilling (“MWD”) tools, logging-while-drilling (“LWD”) tools, downhole motors, underreamers, section mills, hydraulic disconnects, jars, vibration or dampening tools, other components, or combinations of the foregoing.

In general, the downhole system may include other downhole drilling tools, components, and accessories such as special valves (e.g., kelly cocks, blowout preventers, and safety valves). Additional components included in the downhole system may be considered a part of the drilling tool assembly the drill string or a part of the BHA 106, depending on their locations in the downhole system.

The bit in the BHA may be any type of bit suitable for degrading downhole materials. For instance, the bit may be a drill bit suitable for drilling the earth formation. Example types of drill bits used for drilling earth formations are fixed-cutter or drag bits. In other embodiments, the bit may be a mill used for removing metal, composite, elastomer, other materials downhole, or combinations thereof. For instance, the bit may be used with a whipstock to mill into casing lining the wellbore The bit may also be a junk mill used to mill away tools, plugs, cement, other materials within the wellbore or combinations thereof. Swarf or other cuttings formed by use of a mill may be lifted to the surface or may be allowed to fall downhole. The bit may include one or more cutting elements for degrading the earth formation.

The BHA may further include components for directing or steering a trajectory of the bit. For example, the BHA may include a rotary steerable system (RSS) and/or a directional downhole motor. Based on the mechanisms of these steering systems, the BHA may be directed underground to, around, and/or with respect to one or more downhole targets. In many cases, it may be advantageous to simulate, quantify, and conceptualize the behavior of the bit (e.g., in isolation) in response to steering by the steering system(s). In some embodiments, the downhole system includes or is associated with one or more client devices with a bit behavior system implemented thereon (e.g., implemented on one, several, or across multiple client devices). The bit behavior system may facilitate simulating and determining behavior characteristics of one or more downhole tools, such as the bit.

In some embodiments, a bit behavior system is implemented in accordance with one or more embodiments describe herein. In some embodiments, an environment includes one or more server device(s). The server device(s) may include one or more computing devices (e.g., including processing units, data storage, etc.) organized in an architecture with various network interfaces for connecting to and providing data management and distribution across one or more client systems. The server devices may be connected to and may communicate with (either directly or indirectly) one or more client devices through a network. The network may include one or multiple networks and may use one or more communication platforms and/or technologies suitable for transmitting data. The network may refer to any data link that enables transport of electronic data between devices of the environment. The network may refer to a hardwired network, a wireless network, or a combination of a hardwired network and a wireless network. In one or more embodiments, the network includes the internet. The network may be configured to facilitate communication between the various computing devices via well-site information transfer standard markup language (WITSML) or similar protocol, or any other protocol or form of communication.

The client device may refer to various types of computing devices. For example, one or more client devices may include a mobile device such as a mobile telephone, a smartphone, a personal digital assistant (PDA), a tablet, a laptop, or any other portable device. Additionally, or alternatively, the client devices may include one or more non-mobile devices such as a desktop computer, server device, surface or downhole processor or computer (e.g., associated with a sensor, system, or function of the downhole system), or other non-portable device. In one or more implementations, the client devices include graphical user interfaces (GUI) thereon (e.g., a screen of a mobile device). In addition, or as an alternative, one or more of the client devices may be communicatively coupled (e.g., wired or wirelessly) to a display device having a graphical user interface thereon for providing a display of system content. The server device(s) may similarly refer to various types of computing devices. Each of the devices of the environment may include features and/or functionalities described below.

The environment may include a bit behavior system implemented on one or more computing devices. The bit behavior system may be implemented on one or more client device, server devices, and combinations thereof. Additionally, or alternatively, the bit behavior system may be implemented across the client devices and/or the server devices such that different portions or components of the bit behavior system are implemented on different computing devices in the environment. In this way, the environment may be a cloud computing environment, and the bit behavior system may be implemented across one or more devices of the cloud computing environment in order to leverage the processing capabilities, memory capabilities, connectivity, speed, etc., that such cloud computing environments offer in order to facilitate the features and functionalities described herein.

In some embodiments, an example implementation of the bit behavior system is described herein, according to at least one embodiment of the present disclosure.

The bit behavior system may include a data manager, a downhole model engine for generating a downhole model, and a simulation engine. The bit behavior system may also include a data storage having bit geometry data, operational parameter data, bit behavior characteristics, and formation data stored thereon. While one or more embodiments described herein describe features and functionalities performed by specific components of the bit behavior system, it will be appreciated that specific features described in connection with one component of the bit behavior system may, in some examples, be performed by one or more of the other components of the bit behavior system.

By way of example, one or more of the data receiving, gathering, or storing features of the data manager may be delegated to other components of the bit behavior system. As another example, while a simplified downhole model may be generated by a downhole model engine, in some instances, some or all of these features may be performed by the simulation engine (or other component of the bit behavior system). Indeed, it will be appreciated that some or all of the specific components may be combined into other components and specific functions may be performed by one or across multiple components of the bit behavior system.

Additionally, the bit behavior system has been described as implemented on a client device of the downhole system, it should be understood that some or all of the features and functionalities of the bit behavior system may be implemented on or across multiple client devices and/or server devices. For example, data may be input and/or received by the data manager on a (e.g., local) client device, and the downhole model may be generated and/or simulated on one or more of a remote, server, or cloud device. Indeed, it will be appreciated that some or all of the specific components may be implemented on or across multiple client devices and/or server devices, including individual functions of a specific component being performed across multiple devices.

As mentioned above, the bit behavior system includes a data manager. The data manager may receive a variety of types of data associated with the downhole system and may store the data to the data storage. The data manager may receive the data from a variety of sources, such as from sensors, surveying tools, downhole tools, other (e.g., client) devices, user input, etc.

In some embodiments, the data manager receives downhole tool data. The downhole tool data may include information associated with the drilling tool assembly of the downhole system. For example, the downhole tool data may identify the components and configuration of the drilling tool assembly, such as a number of lengths of drill pipe, or the componentry and makeup of a BHA.

In some embodiments, the downhole tool data includes bit data, or information associated with a downhole tool of the drilling tool assembly, such as a drill bit. The bit data may indicate the type of the drill bit and may identify a shape or geometry of the drill bit. The bit data may include information associated with one or more cutting elements of the bit, such as their location, orientation, type, shape, size, geometry, and/or wear state. The bit data may indicate a material composition or makeup of the bit and/or the cutting elements.

In some embodiments, the downhole tool data includes information associated with a steering system of the drilling tool assembly. For example, the downhole tool data may indicate a type of steering assembly, such as an RSS, or a directional downhole motor steering system. The downhole tool data may identify the components of the steering system, such as stabilizers, subs (e.g., flex and/or bent subs), actuators, bearings, bent housings, blades, pads, or any other component, as well as their locations. The downhole tool data may indicate an operation or function of the steering system. For example, the downhole tool data may indicate a biasing direction or steering direction of the steering system. The downhole tool data may indicate a direction or orientation (e.g., toolface orientation) of one or more components, such as an orientation of a bent or flex sub, of the bit, etc. The downhole tool data may indicate an azimuth and/or inclination of the drill string at one or more locations or measurement depths.

In some embodiments, the downhole tool data includes information associated with the (e.g., local) geometry of the BHA and/or steering system. For example, an RSS may operate based on bending sections of the BHA (e.g., utilizing one or more stabilizers as fulcrums) in order to effectuate a change of direction at the bit. The downhole tool data may include information that may identify, or may facilitate determining, the geometry of one or more portions or components of the steering system and/or BHA in order to facilitate the modeling and/or simplifying features of the bit behavior system described herein. In another example, a directional downhole motor steering system may operate based on a motor housing being able to actuate in order to bend and/or angle in order to direct the bit in a corresponding direction. The downhole tool data may accordingly include information that may identify, or facilitate determining, the associated geometry (e.g., geometry data).

In some embodiments, the downhole tool data includes information associated with a (e.g., planned or existing) wellbore. For example, the downhole tool data may indicate a length, depth, size, shape, and/or trajectory of the wellbore. In some embodiments, the data manager receives formation data. The formation data may include information associated with a formation in which a downhole tool will traverse, penetrate, or is otherwise located. For example, the formation data may include information about the geological characteristics of the rock that may be encountered during one or more downhole operations. For instance, the formation data may indicate a material or composition of the formation including a hardness of the formation. The formation data may indicate one or more layers or boundaries of the formation including an orientation or dip of the layers. The formation data may indicate the presence of different particles or modules dispersed throughout (e.g., layers of) the formation, including the material and hardness of the particles. The formation data may indicate the presence of holes or cavities dispersed throughout the formation. The formation data may indicate a degree of homogeneity or uniformity of the formation (e.g., with respect to the particles and/or cavities). The formation data may include data from gamma ray sensors, resistivity sensors, porosity sensors, density sensors, sonic sensors, calipers, core samples, or any other formation data.

The data manager may store any of the information associated with the downhole tool and/or drilling tool assembly to the data storage as downhole tool data.

In some embodiments, the data manager receives user input. The data manager may receive the user input, for example, via any of the client devices and/or server devices. Any of the data described herein may be input or augmented via the user input. For example, in some instances, some or all of the downhole tool data is received by the data manager as user input. The user input may be received in association with one or more functions or features of the bit behavior system, such as part of generating the downhole model, or any other feature described herein.

In some embodiments, the data manager receives operational parameter data. The operational parameter data may be any information associated with an operation or function, either actual, planned, simulated, or otherwise, of the downhole system. For example, the operational parameter data may be associated with a drilling operation of the downhole system. The operational parameter data may be associated with a steering operation of the downhole system. The operational parameter data may be associated with any other operation of the downhole system, such as the transit or tripping of one or more downhole tools.

The operational parameter data may indicate one or more parameters of an associated operation. For example, the operational parameter data may indicate a weight on bit (WOB) and/or a rate of penetration (ROP) of a downhole tool. The operational parameter data may indicate a rotational speed (rotations per minute or RPM) of one or more components. For example, the operational parameter data may indicate a surface RPM provided or exhibited by a surface component of the downhole system, such as due to a drill rig rotating the drilling string and/or drilling tool assembly. The operational parameter data may indicate a downhole or motor RPM. The motor RPM may indicate a rotational speed of a downhole tool driven by a downhole motor. The motor RPM may be independent of the surface RPM. For example, in some cases, a downhole motor may drive a downhole tool to rotate in addition to the rotation of the (e.g., rest of the) drill string from the surface RPM. In some cases, the downhole system may not rotate with a surface RPM, and a downhole motor may drive a downhole tool to rotate solely based on the motor RPM. In this way, the rotation of a downhole tool may be driven by either a surface RPM, motor RPM, or a combination of both.

In this way, the data manager receives a variety of data in order to facilitate the techniques described herein. The data manager may receive the data from a variety of sources. For example, some of the data may be accessed by the data manager in a database, record, or library. The data may be observed, measured, or recorded, for example, by sensors or measurement devices of the downhole system. In some embodiments, the data is received from another computing device or system associated with the bit behavior system. As mentioned above, some of the data may be received or input as user input by an operator or administrator of the bit behavior system.

In some embodiments, some or all of the data is generated, determined, or created to characterize planned, hypothetical, or simulated situations and/or operations of the downhole system. For example, while the data received and/or stored by the data manager has been described herein with respect to an implementation of a downhole tool and/or downhole system in a wellbore, it should be understood that in some embodiments, some or all of the data is associated with a planned or simulated implementation of a downhole operation. For example, the data may be data associated with a downhole tool implemented in a wellbore but may be for the purposes of simulating or testing one or more potential further operations of the downhole tool. In another example, the data may be associated purely with planning or simulating a potential or future wellbore. In this way, the techniques described herein may be applicable to a wide variety of situations and applications including both physical (existing) implementations and virtual, simulated, or planned implementations.

In some embodiments, an example implementation of a steering system that may be utilized to steer a downhole tool is described herein. The steering system may be a point-the-bit steering system such as may be achieved through a directional or bent downhole motor. The steering system may be implemented in a wellbore and may be included as part of a BHA of the downhole system. The BHA and/or the steering system may be connected to one or more lengths of drill pipe in order to position the steering system and/or the BHA in the wellbore and/or to apply rotation, apply force, etc., to the downhole components as described herein.

The steering system may be connected to a downhole tool, such as a bit. As mentioned above, in some cases, it may be desirable to change a direction or orientation of the bit in order to steer the bit. To achieve this, the steering system may include one or more components that have an articulating flexure or a joint that are capable of actuating to achieve a bend or angle. For example, the joint may be implemented as part of a downhole motor of the steering system that has an articulable bent housing design in order to change the orientation of the bit. The joint may bend at a bend point and may bend with a bend angle. The bend angle may be an angle measured between a longitudinal axis of the bit and an adjacent, bent portion of the BHA above the joint. In this way the bend angle may be a measure of the degree or level of articulation of the joint.

The steering system may include a stabilizer to facilitate directing the bit. The stabilizer may be a component of the steering system that is configured to engage the wellbore. For example, the stabilizer may be configured to engage the wellbore and maintain a relative position of the BHA in the wellbore, such as in the center, or substantially in the center, of the wellbore. In some embodiments, this stabilizing and/or centering function of the stabilizer facilitates directing the bit based on the articulation of the joint. For example, as the joint bends, the bottom or free end of the BHA (e.g., the bit) may be biased or may move toward the wall of the wellbore. The bit may engage the wall of the wellbore, driving the joint in an opposite direction.

In some embodiments, the stabilizer engages the wellbore and provides an opposite, balancing force to the bit such that the bit may pivot or rotate about a pivot point. In this way, the stabilizer may act as a fulcrum for directing the bit and driving it (at least somewhat) into the wall of the wellbore.

In some embodiments, an axial force, or WOB is applied to the steering system and/or BHA through the drill string. The WOB may be a force resulting from the weight of the drilling tool assembly connected above or uphole of the BHA, may be an applied force from the drill rig at the surface, or a combination of both. Due to the bit being angled from a centerline or longitudinal axis of the wellbore, the axial WOB may be transferred to the bit with at least some lateral component. This may result in the bit engaging (and forming) the bottom of the wellbore at an angle, thus steering the bit.

In some embodiments, the steering system is rotated with a surface RPM. The surface RPM may be a driven rotation of the entirety of the drill string from surface equipment such as the drill rig. For example, the surface RPM may be transmitted to the steering system and/or BHA through the lengths of drill pipe as described herein. In some embodiments, the bit is rotated with a motor RPM. The motor RPM may be a rotation of the bit driven by a downhole motor (e.g., mud motor) of the steering system. In this way, the rotation of the bit may be driven by (and/or may be described by) the surface RPM, the motor RPM, or a combination of both.

As mentioned above, the bit behavior system includes a downhole model engine. In some embodiments, the downhole model engine models the steering system including the BHA and the bit. In some embodiments, the model engine determines the geometry associated with the steering system. For example, based on the downhole tool data, the model engine may determine the bend angle of the joint. The model engine may identify the location of the bend point. For example, in some cases, the bend point may be offset, or not aligned with the axis of the wellbore. This may be due to the bent or offset nature of the steering system as described above. Similarly, the model engine may identify the location of the pivot point about which the bit pivots. For example, in some cases, the pivot point may be offset, or not aligned with the axis of the wellbore. This may be due to the stabilizer not being exactly the size of the gauge or diameter of the wellbore, and as the stabilizer is biased toward one side of the wellbore, the pivot point may accordingly be slightly offset from the axis. In some embodiments, a gap may be present between the stabilizer and the wellbore due to this effect.

In some embodiments, the model engine determines a bend length. The bend length may be a length measured from a downhole end of the bit to the pivot point. For example, the bend length may be a measure from the joint of the steering system to the furthest downhole extent of the BHA.

The model engine may determine the various loading, forces, or other dynamics applied to the bit. For example, the model engine may identify from the downhole tool data the WOB applied to the BHA. The model engine may identify from the downhole tool data the surface RPM and/or the motor RPM. The model engine may determine the various lengths, angles, positions, etc., of the geometry of the BHA and/or the steering system, as well as determining the applied forces, rotations, etc., in order that the model engine may model or simulate an operation of the downhole system and may predict or determine the resulting response or behavior of the bit. The model engine may determine any other dynamic, such as rate of penetration (ROP) applied or exhibited by the downhole system in order to model the response of the bit.

As discussed above, the downhole system may include a number of components and/or tools positioned throughout the length of the drilling tool assembly. For example, the drilling tool assembly may include many lengths of drill pipe, collars, subs, tool joints, stabilizers, drill bits and reamers, steering systems, and other components. This intricate system of componentry may represent a complex and dynamic system which may be difficult to model and characterize. For example, the components may all be (at least indirectly) connected, and the movement, forces, torques, stresses, etc., exhibited by one component may accordingly affect those exhibited by other components. Additionally, many of the components may engage the wellbore wall, which may further affect the behavior of one or more components. Further, the alignment (or lack thereof) of the components of the downhole system with the wellbore axis may further complicate the modeling of component behavior. For example, as discussed above, the bend point and the pivot point may be offset from the axis of the wellbore. Accordingly, the BHA, steering system, bit, etc., may not be aligned with the axis of the wellbore, making it computationally more difficult to model the behavior of the bit (e.g., in relation to the wellbore). This effect may be even more evident when considering that similar misalignment may be propagated throughout many components of the drill string, as the drill string and the wellbore may not typically be exactly straight, aligned, and vertical, but may often exhibit bent and/or curved geometries. Thus, attempting to simulate bit behavior by modeling and accounting for all of the components, details, and geometries of the downhole system may be overly complicated, and may be computationally difficult and/or slow.

In some embodiments, the model engine generates a simplified downhole model. The simplified downhole model may include a simplified representation of one or more of the bit, the BHA, and/or the steering system. For example, based on the downhole tool data and/or based on the lengths, positions, angles, etc., of the geometries discussed above, the model engine may determine an effective bend point. The effective bend point may be a point located at the intersection between a longitudinal axis of the bit and the wellbore axis. In this way, the effective bend point may be located at and/or aligned with the axis. Due to the geometry of the steering system, the effective bend point may be located downhole from the bend point.

In some embodiments, the model engine generates a simplified downhole model to facilitate simulating and/or characterizing the behavior of the bit. For example, the model engine may determine an effective bend length for the simulate downhole model. The effective bend length may be measured from the end of the bit to the effective bend point. The effective bend length may extend from the wellbore axis based on the effective bend point being located at the wellbore axis. For example, the effective bend length may be angled from the wellbore axis by an effective bend angle. Due to the mechanics of the bending action of the steering system (e.g., the geometry of the steering system pivoting about the pivot point), the effective bend length may be shorter than the bend length, and the effective bend angle may be smaller than the bend angle. In some embodiments, the model engine determines, based on the geometries discussed above, the effective bend angle in order to facilitate determining the effective bend length, for example, by implementing trigonometric analyses. For example, the model engine may determine an offset distance of the end or tip of the bit from the wellbore axis. Based on the offset distance and the effective bend angle, the model engine may calculate the effective bend length using trigonometric functions. In this way, the simplified downhole model may simulate the geometry of the steering system as if it were aligned and/or bent at the wellbore axis. For example, the simplified model may represent the rest of the drill string as straight or aligned with the wellbore axis. Accordingly, the simplified model may simplify the downhole system from a complex, detailed system, to a much simpler system that is focused on the bit and its relation to the wellbore.

The simplified model may facilitate modeling the behavior and/or response of the bit to one or more applied downhole stimuli. For example, one or more of the WOB, the surface RPM, and the motor RPM may be simulated for the bit based on the simplified geometry of the simplified downhole model with respect to the wellbore. In some embodiments, the effective bend point is modeled as a fixed point, and one or more applied downhole dynamics may be simulated for the bit at the (e.g., fixed) effective bend point. For example, the WOB may be simulated as an applied force on the bit from the effective bend point (e.g., taking into account the component forces due to the effective bend angle). In another example, the surface RPM may be applied to the bit from the effective bend point by simulating the effective bend length (e.g., angled at the effective bend angle) rotating about the wellbore axis. In another example, the motor RPM may be applied to the bit from the effective bend point by simulating the bit (and/or the effective bend length) rotating about its own longitudinal axis at the motor RPM. In some embodiments, both the motor RPM and the motor RPM may be applied in this way to represent a compound rotation of the bit. In this way, the behavior of the bit may be simulated in a simplified manner by focusing in on the specific angles, lengths, forces, etc., relevant to the bit while not considering some of the more detailed complexities of the intricate downhole system as a whole.

In some embodiments, an example implementation of a steering system that may be utilized to steer a downhole tool is described herein. The steering system may be an RSS. As will be described in detail below, the techniques described herein may be equally applicable to downhole systems implementing an RSS, for example, in addition to or as an alternative to a directional downhole motor steering system.

The steering system may be included as part of a BHA of the downhole system, and may be connected to one or more lengths of drill pipe at an uphole end in order to position the steering system and/or the BHA in the wellbore, and/or to apply rotation, force, etc., to the downhole components as has been described herein.

The steering system may be a point-the-bit steering system and may direct or steer the bit by forcing the bending of one or more components. For example, the steering system may apply a biasing force to a flexible component uphole of the bit. The biasing force may be applied based on a stabilizer, actuator, or other downhole tool contacting the wall of the wellbore. The biasing force may cause the flexible component to bend. For example, the steering system may include one or more stabilizers which may contact the wall of the wellbore and may counteract the biasing force. This may cause the flexible component to bend between the stabilizers, with the stabilizers acting like fulcrums for the bending of the flexible component. Based on the bit being positioned downhole from the bending of the flexible component, the bit may accordingly be pointed or directed in an opposite direction of the bend. In this way, the steering system may direct the bit in order to effectively steer the bit.

The model engine may determine the geometry associated with the steering system. As described above in connection with the steering system, the geometry of the steering system may exhibit one or more complexities that may make a detailed analysis of the behavior of the bit computationally difficult. For example, the flexible component being bent presents a complicated analysis of bit dynamics. Additionally, the bend of the flexible component results in the bit and/or one or more other (e.g., uphole) components of the drill string being offset by a bend angle. As another example, the bit may be offset at an angle relative to the wellbore axis. This may be further complicated by the fact that the fulcrum points of the stabilizers for effectuating the bend of the flexible component may also be offset from the wellbore axis (e.g., as illustrated by the gaps). Accordingly, applying a WOB and/or a surface RPM (or any other downhole dynamic) to the steering system with the complexities of the geometry may be computationally demanding and inefficient for determining the resulting behavior of the bit.

As discussed above, the model engine may generate a simplified downhole model applicable to the steering system. For example, based on the downhole tool data, and/or based on the various lengths, positions, angles, etc., that the model engine may determine for the steering system, the model engine may determine an effective bend point. The effective bend point may be a point located at the intersection between a longitudinal axis of the bit and the wellbore axis. In this way, the effective bend point may be located at and/or aligned with the axis.

Similar to that described above, the model engine may generate the simplified downhole model to facilitate simulating and/or characterizing the behavior of the bit. The model engine may determine an effective bend length for the simulated downhole model based on an effective bend angle and an offset distance. The simulated downhole model may simulate the geometry of the steering system as if it consisted of straight sections and/or straight components, and as if those components were effectively bent at the wellbore axis. Accordingly, the simplified model may simplify the downhole system from a complex, detailed system, to a much simpler system that is focused on the bit and its relation to the wellbore.

Just as discussed above, the simplified model may facilitate modeling the behavior and/or response of the bit to one or more applied downhole dynamics. For example, the effective bend point may be modeled as a fixed point, and the WOB and/or surface RPM may be simulated as applied to the bit in relation to (e.g., from) the effective bend point. However, in implementations where no directional downhole motor is implemented, the bit response may be simulated via the simplified downhole model without incorporating an applied motor RPM.

In some embodiments, an example workflow of the bit behavior system is described herein. As mentioned above, the bit behavior system includes a simulation engine. The simulation engine may run a simulation of the downhole system, and more specifically of the bit, by implementing the simplified downhole model in order to determine one or more bit behavior characteristics representing a simulated response or behavior of the bit.

In some embodiments, the simulation engine applies the downhole tool data to the simplified downhole model. For example, the simulation engine may incorporate the downhole tool data to account for various aspects of the bit such as bit type, size, shape, geometry, general wear state, etc. The simulation engine may incorporate the downhole tool data to account for various aspects of the cutting elements and/or contact elements of the bit, such as the location, orientation, number, type, shape, size, geometry, and individual wear state of the cutting elements and/or the contact elements. The downhole tool data may be incorporated in order to account for a material or composition of the bit and/or cutting elements. In this way, the simulation engine may simulate various details of the bit that may be relevant to determining an accurate simulated response of the bit.

In some embodiments, the simulation engine applies the operational parameter data to the simplified downhole model. For example, as discussed above, one or more applied downhole dynamics may be simulated for the bit based on the simplified downhole model, such as a WOB, surface RPM, motor RPM, or any other relevant metric (e.g., ROP). As mentioned above, these applied dynamics may be applied to the bit based on the modified and/or simplified geometry of the simplified downhole model in order to capture the response of the bit without modeling or simulation some of the more complex details of other components of the downhole system. For example, the WOB, surface RPM and/or motor RPM may be incorporated based on a (e.g., fixed) effective bend point and based on applying these forces, rotations, etc., from the effective bend point. In this way, the simulating engine may simulate various operational parameters or conditions of interest in order to determine a corresponding response of the bit.

In some embodiments, the simulation engine applies the formation data to the simplified downhole model. For example, the simulation engine may simulate the bit interacting with (e.g., forming) the wellbore based on the wellbore having one or more properties of a particular formation of interest. The simulation engine may simulate one or more geological characteristics of the rock of a formation. The simulation engine may simulate one or more layers (including a formation dip) of the formation. The simulation engine may simulate one or more particles, modules, and/or cavities dispersed throughout the formation. In some embodiments, the simulation engine simulates a formation that is non-uniform or non-homogeneous. For example, the simulation engine may simulate a formation that has one or more compositions, properties, characteristics, materials, etc., that are not uniform or consistent. For instance, the simulated formation may exhibit variations in lithology, porosity, permeability, mineral composition, physical and/or chemical characteristics, structural complexity, fluid presence and/or saturation, or any other (e.g., non-uniform) property. In this way, the simulation engine may simulate the relevant details of a particular formation of interest in order to determine a corresponding response of the bit.

Based on running a simulation and implementing the simplified downhole model, and based on the various bit, operational, and/or formation characteristics incorporated in the simulation, the simulation engine may determine one or more bit behavior characteristics. The bit behavior characteristics may include various metrics for characterizing how the bit may move, wear, steer, respond, perform, or otherwise behave to the specific conditions of the simulation. For example, the bit behavior characteristics may characterize the forces and loading across the bit, rock removal by the bit, and shock and vibrations (e.g., accelerations) experienced by the bit. In some embodiments, the simulation engine determines one or more bit behavior characteristics related to one or more of durability, steerability, stability, and efficiency of the bit.

In some embodiments the simulation engine determines one or more resulting forces or contact forces based on the bit contacting the wellbore wall. For example, the simulation engine may determine the forces on one or more (or each) of the cutting elements and/or contact elements of the bit. In another example, the simulation engine may determine the forces on one or more gauge pads or other contacting surfaces of the bit designed to manage the depth of cut of the bit. The simulation engine may determine the forces in 3 dimensions and/or may determine the 3-dimensional components of the forces on the cutting elements and/or engagement elements.

In some embodiments, the determined forces facilitate determining a durability characteristic for the bit. For example, the determined forces may facilitate characterizing a level or degree of wear of the cutting elements. For instance, the simulation engine may determine a workrate for some or all of the cutting elements (or for the bit generally). The workrate may be associated with a force observed for the cutting element at a corresponding velocity. The simulation engine may identify whether certain cutting elements or certain areas of the bit are being overloaded in order to determine how the bit may wear.

In some embodiments, the determined forces facilitate determining a steerability characteristic. For example, the determined forces may include a side cutting force associated with an ability for the bit to cut laterally, or to cut with cutting elements that are located on a lateral side of the bit. The side cutting force may be associated with an ability of the bit to turn, steer, or otherwise form the wellbore in a lateral direction. For example, the side cutting forces may be associated with the ability of the bit to produce a dogleg.

In some embodiments, the determined forces facilitate determining a stability characteristic. For example, as mentioned, the determined forces may be 3-dimensional. In some embodiments, the net force of the bit (e.g., sum of all forces acting on all of the cutting elements) have, at least partially, a lateral or sideways component. Thus, the resulting net force may be an imbalance force which may tend to bias or push the bit in a certain direction. The simulation engine may determine the imbalance force in order to characterize the stability of the bit. For example, the imbalance force may help to characterize the ability of the bit to stay straight during a straight drilling operation, and/or to stay turned during a steering operation.

In some embodiments, the simulation engine determines various other metrics or measurements associated with durability. For example, the simulation engine may determine one or more of torque, bending, stress, strain, shock, vibration, or any other relevant metric for the bit and/or for one or more other downhole components. These metrics may facilitate understanding how various components of the downhole system may wear in response to the specific conditions of the simulation. For example, understanding the torque and bending moments exhibited by the bit may help to understand the loading on the bit or other downhole components, and may facilitate determining wear experienced by these components.

In some embodiments, the simulation engine determines one or more efficiency characteristics. For example, the simulation engine may determine a rate of penetrating ROP for the bit. The simulation engine may determine the quality of the wellbore formed under the simulated conditions. For example, the simulation engine may identify one or more areas of wellbore enlargement, such as may be due to applying a surface RPM while bending or directing the bit (e.g., with the downhole directional motor). In this way the simulation engine may determine various bit behavior characteristics to facilitate understanding specific details about how the bit may respond to the specific conditions simulated for the downhole operation. This may be facilitated by the simplified downhole model (e.g., the simplified geometry of the simplified downhole model). For example, the behavior, response, and/or effect of one or more other downhole components may be ignored or not considered in order to focus on the behavior of the bit alone. This may help to increase the computational efficiency, speed, accuracy, etc., with which the bit behavior system may determine the bit behavior characteristics, for example, as opposed to analyzing a more complex, in-depth, representation of the downhole system.

In some embodiments, the simulation engine generates one or more reports including some or all of the features described below. In some embodiments, the report is associated with specific operational parameters for an associated simulated downhole operation. For example, the report may be associated with the operational parameters for a simulated operation having an effective bend angle of 1°, a surface RPM of 60, and a motor RPM of 200. In some embodiments, the report illustrates or depicts a representation of the wellbore resulting from the simulation of the downhole operation. For example, the report may include a horizontal, top-down cross-section, and a profile of the wellbore. The cross-section and the profile may illustrate a hole-enlargement effect of the operation on the wellbore. The cross-section may illustrate a rotational path of the bit. For example, the cross-section may show that the bit experienced a certain degree of whirl as it formed the wellbore due to, for example, the surface RPM being applied in conjunction with the effective bend angle of a directional downhole motor.

In some embodiments, the report illustrates a representation of one or more forces acting on one or more of the cutting elements of the bit. For example, the report may depict a normal force and/or a tangential force on one or more of the cutting elements. This may facilitate identifying higher forces exhibited by one or more cutting elements or areas of the bit, such as to facilitate identifying an (e.g., net) imbalance force for the bit. The report may depict any of the features described here, and additionally may omit any of the features described for the report. The report may provide a representation of any of the bit behavior characteristics described herein.

In some embodiments, a method or a series of acts for predicting behavior of a downhole tool implemented in a wellbore is described herein.

In some embodiments, the method includes an act of receiving geometry data associated with the downhole tool, wherein the geometry data indicates a bend angle of the downhole tool based on the downhole tool being bent at a bend point. For example, the downhole tool may include a stabilizer, and the downhole tool may be bent based on the stabilizer engaging a wall of the wellbore. The downhole tool may bend about a fulcrum point at the stabilizer. The fulcrum point may not be aligned with the longitudinal axis of the wellbore. Similarly, the bend point may not be positioned at the longitudinal axis of the wellbore. The geometry data may further indicate a bend length of the downhole tool. In some embodiments, the downhole tool is a bottom hole assembly of a downhole system, and the bottom hole assembly includes a drill bit.

In some embodiments, the method includes receiving formation data. For example, the formation data may be associated with a formation that is not homogeneous. The formation data may indicate a formation dip of the formation.

In some embodiments, the method includes an act of, based on the geometry data, generating a simplified model of the downhole tool including determining an effective bend point based on a longitudinal axis of the wellbore, and determining an effective bend angle based on the longitudinal axis of the wellbore. The effective bend angle may be less than the bend angle. The bend point may be located downhole from the bend point. In some embodiments, the effective bend point is determined at an intersection between a longitudinal axis of the downhole tool and the longitudinal axis of the wellbore. In some embodiments, generating the simplified model includes determining an effective bend length based on the effective bend point.

In some embodiments, the method includes an act of receiving operational parameters for the downhole tool. For example, the operational parameters may include a weight on bit (WOB) associated with the downhole tool. The operational parameters may include a surface RPM associated with a rotational speed of the downhole tool above the bend point, and a motor RPM associated with a rotational speed of the downhole tool below the bend point.

In some embodiments, the method includes an act of simulating an operation of the downhole tool based on applying the operational parameters to the simplified model. The operation may be a steering operation. For example, simulating the operation may include applying the WOB, surface RPM, and/or the motor RPM to the simplified model. In some embodiments, the operational parameters are applied to the downhole tool based on the effective bend angle and at the effective bend point. In some embodiments, the formation data is incorporated to simulate the downhole tool in a specific formation of interest.

In some embodiments, the method includes an act of determining one or more behavior characteristics of the downhole tool based on the simulation. For example, the one or more behavior characteristics may include one or more of an imbalance force exerted on the downhole tool, a side cutting force of the downhole tool, and a shock and vibration on the downhole tool. The one or more behavior characteristics may include one or more of forces exerted on cutting elements of the downhole tool, and a workrate of the cutting elements. The one or more behavior characteristics may include torque and bending associated with the downhole tool. The one or more behavior characteristics may include one or more of an enlargement of the wellbore and a quality of the wellbore.

In some embodiments, certain components may be included within a computer system. One or more computer systems may be used to implement the various devices, components, and systems described herein.

The computer system includes a processor. The processor may be a general-purpose single- or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor may be referred to as a central processing unit (CPU). Although just a single processor is described, in an alternative configuration, a combination of processors (e.g., an ARM and DSP) could be used.

The computer system also includes memory in electronic communication with the processor. The memory may include computer-readable storage media and may be any available media that may be accessed by a general purpose or special purpose computer system. Computer-readable media that store computer-executable instructions are non-transitory computer-readable media (device). Computer-readable media that carry computer-executable instructions are transmission media. Thus, by way of example and not limitations, embodiment of the present disclosure may comprise at least two distinctly different kinds of computer-readable media: non-transitory computer-readable media (devices) and transmission media.

Both non-transitory computer-readable media (devices) and transmission media may be used temporarily to store or carry software instructions in the form of computer readable program code that allows performance of embodiments of the present disclosure. Non-transitory computer-readable media may further be used to persistently or permanently store such software instructions. Examples of non-transitory computer-readable storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which may be used to store program code in the form of computer-executable instructions or data structures and which may be accessed by a general purpose or special purpose computer, whether such program code is stored or in software, hardware, firmware, or combinations thereof.

Instructions and data may be stored in the memory. The instructions may be executable by the processor to implement some or all of the functionality disclosed herein. Executing the instructions may involve the use of the data that is stored in the memory. Any of the various examples of modules and components described herein may be implemented, partially or wholly, as instructions stored in memory and executed by the processor. Any of the various examples of data described herein may be among the data that is stored in memory and used during execution of the instructions by the processor.

A computer system may also include one or more communication interfaces for communicating with other electronic devices. The communication interface(s) may be based on wired communication technology, wireless communication technology, or both. Some examples of communication interfaces include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

The communication interfaces may connect the computer system to a network. A “network” or “communications network” may generally be defined as one or more data links that enable the transport of electronic data between computer systems and/or modules, engines, or other electronic devices, or combinations thereof. When information is transferred or provided over a communication network or another communications connection (either hardwired, wireless, or a combination of hardwired or wireless) to a computing device, the computing device properly views the connection as a transmission medium. Transmission media may include a communication network and/or data links, carrier waves, wireless signals, and the like, which may be used to carry desired program or template code means or instructions in the form of computer-executable instruction or data structures and which may be accessed by a general purpose or special purpose computer.

A computer system may also include one or more input devices and one or more output devices. Some examples of input devices include a keyboard, mouse, microphone, remote control device, button, joystick, trackball, touchpad, and lightpen. Some examples of output devices include a speaker and a printer. One specific type of output device that is typically included in a computer system is a display device. Display devices used with embodiments disclosed herein may utilize any suitable image projection technology, such as liquid crystal display (LCD), light-emitting diode (LED), gas plasma, electroluminescence, or the like. A display controller may also be provided, for converting data stored in the memory into one or more of text, graphics, or moving images (as appropriate) shown on the display device.

The various components of the computer system may be coupled together by one or more buses, which may include one or more of a power bus, a control signal bus, a status signal bus, a data bus, other similar components, or combinations thereof.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various embodiments.

Further, upon reaching various computer system components, program code in the form of computer-executable instructions or data structures may be transferred automatically or manually from transmission media to non-transitory computer-readable storage media (or vice versa). For example, computer executable instructions or data structures received over a network or data link may be buffered in memory (e.g., RAM) within a network interface module (NIC), and then eventually transferred to computer system RAM and/or to less volatile non-transitory computer-readable storage media at a computer system. Thus, it should be understood that non-transitory computer-readable storage media may be included in computer system components that also (or even primarily) utilize transmission media.

The following description from ¶¶ [0176]-[01XX] includes various embodiments that, where feasible, may be combined in any permutation. For example, the embodiment of ¶ [0176] may be combined with any or all embodiments of the following paragraphs. Embodiments that describe acts of a method may be combined with embodiments that describe, for example, systems or devices. Any permutation of the following paragraphs is considered to be hereby disclosed for the purposes of providing “unambiguously derivable support” for any claim amendment based on the following paragraphs. Furthermore, the following paragraphs provide support such that any combination of the following paragraphs would not create an “intermediate generalization.

The following description from ¶¶ [0177]-[0194] includes various embodiments that, where feasible, may be combined in any permutation. For example, the embodiment of ¶ [0177] may be combined with any or all embodiments of the following paragraphs. Embodiments that describe acts of a method may be combined with embodiments that describe, for example, systems and/or devices. Any permutation of the following paragraphs is considered to be hereby disclosed for the purposes of providing “unambiguously derivable support” for any claim amendment based on the following paragraphs. Furthermore, the following paragraphs provide support such that any combination of the following paragraphs would not create an “intermediate generalization.”

In some embodiments, a method of predicting behavior of a downhole tool implemented in a wellbore includes receiving geometry data associated with the downhole tool, wherein the geometry data indicates a bend angle of the downhole tool based on the downhole tool being bent at a bend point. In some embodiments, the method includes based on the geometry data, generating a simplified model of the downhole tool including determining an effective bend point based on a longitudinal axis of the wellbore, and determining an effective bend angle 456 based on the longitudinal axis 450 of the wellbore 441. In some embodiments the method includes receiving operational parameters for the downhole tool. In some embodiments, the method includes simulating an operation of the downhole tool based on applying the operational parameters to the simplified model, and determining one or more behavior characteristics of the downhole tool based on the simulation.

In some embodiments, the operational parameters include a weight on bit (WOB) associated with the downhole tool, and simulating the operation of the downhole tool includes applying the WOB to the simplified model.

In some embodiments, the operational parameters include a surface RPM associated with a rotational speed of the downhole tool above the bend point, and a motor RPM associated with a rotational speed of the downhole tool below the bend point.

In some embodiments, the effective bend angle is less than the bend angle, and the effective bend point is located downhole from the bend point.

In some embodiments, the effective bend point is determined at an intersection between a longitudinal axis of the downhole tool and the longitudinal axis of the wellbore.

In some embodiments, the downhole tool includes a stabilizer, and the downhole tool is bent based on the stabilizer engaging a wall of the wellbore, and the downhole tool bends about a fulcrum point at the stabilizer.

In some embodiments, the fulcrum point is not aligned with the longitudinal axis of the wellbore.

In some embodiments, the bend point is not positioned at the longitudinal axis of the wellbore.

In some embodiments, simulating the operation of the downhole tool further includes applying the operational parameters to the downhole tool based on the effective bend angle and at the effective bend point.

In some embodiments, the one or more behavior characteristics include one or more of an imbalance force exerted on the downhole tool, a side cutting force of the downhole tool, and a shock and vibration on the downhole tool.

In some embodiments, the one or more behavior characteristics include one or more of forces exerted on cutting elements of the downhole tool and a workrate of the cutting elements.

In some embodiments, the one or more behavior characteristics include torque and bending associated with the downhole tool.

In some embodiments, the one or more behavior characteristics include one or more of an enlargement of the wellbore and a quality of the wellbore.

In some embodiments, the method further includes receiving formation data, and applying the operational parameters to the simplified model includes incorporating the formation data to simulate the downhole tool in a specific formation of interest.

In some embodiments, the formation data is associated with a formation that is not homogenous.

In some embodiments, the formation data indicates a formation dip of the formation.

In some embodiments, the operation of the downhole tool is a steering operation of the downhole tool with a downhole motor.

In some embodiments, the downhole tool is a bottom hole assembly of a downhole system, and the bottom hole assembly includes a drill bit.

The embodiments of the bit behavior system have been primarily described with reference to wellbore drilling operations; the bit behavior system described herein may be used in applications other than the drilling of a wellbore. In other embodiments, the bit behavior system according to the present disclosure may be used outside a wellbore or other downhole environment used for the exploration or production of natural resources. For instance, the bit behavior system of the present disclosure may be used in a borehole used for placement of utility lines. Accordingly, the terms “wellbore,” “borehole” and the like should not be interpreted to limit tools, systems, assemblies, or methods of the present disclosure to any particular industry, field, or environment.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method of predicting behavior of a downhole tool implemented in a wellbore, comprising:
receiving geometry data associated with the downhole tool, wherein the geometry data indicates a bend angle of the downhole tool based on the downhole tool being bent at a bend point;
based on the geometry data, generating a simplified model of the downhole tool including:
determining an effective bend point based on a longitudinal axis of the wellbore; and
determining an effective bend angle based on the longitudinal axis of the wellbore;
receiving operational parameters for the downhole tool;
simulating an operation of the downhole tool based on applying the operational parameters to the simplified model; and
determining one or more behavior characteristics of the downhole tool based on the simulation.

2. The method of claim 1 wherein the operational parameters include a weight on bit (WOB) associated with the downhole tool, and simulating the operation of the downhole tool includes applying the WOB to the simplified model.

3. The method of claim 1, wherein the operational parameters include a surface RPM associated with a rotational speed of the downhole tool above the bend point, and a motor RPM associated with a rotational speed of the downhole tool below the bend point.

4. The method of claim 3, wherein the effective bend angle is less than the bend angle, and wherein the effective bend point is located downhole from the bend point.

5. The method of claim 1, wherein the effective bend point is determined at an intersection between a longitudinal axis of the downhole tool and the longitudinal axis of the wellbore.

6. The method of claim 1, wherein the downhole tool includes a stabilizer, the downhole tool being bent based on the stabilizer engaging a wall of the wellbore, and wherein the downhole tool bends about a fulcrum point at the stabilizer.

7. The method of claim 6, wherein the fulcrum point is not aligned with the longitudinal axis of the wellbore.

8. The method of claim 1, wherein the bend point is not positioned at the longitudinal axis of the wellbore.

9. The method of claim 1, wherein simulating the operation of the downhole tool further includes applying the operational parameters to the downhole tool based on the effective bend angle and at the effective bend point.

10. The method of claim 1, wherein the one or more behavior characteristics include one or more of an imbalance force exerted on the downhole tool, a side cutting force of the downhole tool, and a shock and vibration on the downhole tool.

11. The method of claim 1, wherein the one or more behavior characteristics include one or more of forces exerted on cutting elements of the downhole tool and a workrate of the cutting elements.

12. The method of claim 1, wherein the one or more behavior characteristics include torque and bending associated with the downhole tool.

13. The method of claim 1, wherein the one or more behavior characteristics include one or more of an enlargement of the wellbore and a quality of the wellbore.

14. The method of claim 1, further including receiving formation data, and wherein applying the operational parameters to the simplified model includes incorporating the formation data to simulate the downhole tool in a specific formation of interest.

15. The method of claim 14, wherein the formation data is associated with a formation that is not homogenous.

16. The method of claim 14, wherein the formation data indicates a formation dip of the formation.

17. The method of claim 1, wherein the operation of the downhole tool is a steering operation of the downhole tool with a downhole motor.

18. The method of claim 1, wherein the downhole tool is a bottom hole assembly of a downhole system, and wherein the bottom hole assembly includes a drill bit.

19. A system, comprising:
at least one processor;
memory in electronic communication with the at least one processor; and
instructions stored in the memory, the instructions being executable by the at least one processor to:
receive geometry data associated with a downhole tool, wherein the geometry data indicates a bend angle of the downhole tool based on the downhole tool being bent at a bend point;
based on the geometry data, generate a simplified model of the downhole tool including:
determine an effective bend point based on a longitudinal axis of a wellbore; and
determine an effective bend angle based on the longitudinal axis of the wellbore;
receive operational parameters for the downhole tool;
simulate an operation of the downhole tool based on applying the operational parameters to the simplified model; and
determine one or more behavior characteristics of the downhole tool based on the simulation.

20. A computer-readable storage medium including instruction that, when executed by at least one processor, cause the processor to:
receive geometry data associated with a downhole tool, wherein the geometry data indicates a bend angle of the downhole tool based on the downhole tool being bent at a bend point;
based on the geometry data, generate a simplified model of the downhole tool including:
determine an effective bend point based on a longitudinal axis of a wellbore; and
determine an effective bend angle based on the longitudinal axis of the wellbore;
receive operational parameters for the downhole tool;
simulate an operation of the downhole tool based on applying the operational parameters to the simplified model; and
determine one or more behavior characteristics of the downhole tool based on the simulation.
